(19) United States
(12) Patent Application Publication
(10) Pub. No.: US 2025/0359264 A1
(43) Pub. Date: Nov. 20, 2025

(54) LATERAL DIFFUSION METAL OXIDE SEMICONDUCTOR (LDMOS) TRANSISTOR AND METHOD OF MAKING

(71) Applicants: TAIWAN SEMICONDUCTOR MANUFACTURING COMPANY, LTD, Hsinchu (TW); TSMC CHINA COMPANY, LIMITED, Shanghai (CN)

(72) Inventors: Lianjie LI, Hsinchu (TW); Hui Ming ZHANG, Hisnchu (TW); Lu ZHANG, Hsinchu (TW); Xiyue WU, Hsinchu (TW); Xu KE, Hsinchu (TW)

(21) Appl. No.: 19/287,673

(22) Filed: Jul. 31, 2025

Related U.S. Application Data
(63) Continuation of application No. 18/505,257, filed on Nov. 9, 2023.

(30) Foreign Application Priority Data
Oct. 24, 2023 (CN) 202311380777.0

(51) Int. Cl. H10D 64/23; H01L 21/285; H10D 30/01; H10D 30/65; H10D 64/01

(52) U.S. Cl. CPC H10D 64/258; H01L 21/28518; H10D 30/0281; H10D 30/65; H10D 64/015

(57) ABSTRACT

A lateral diffusion metal-oxide-semiconductor (LDMOS) transistor. includes a first gate. The LDMOS transistor further includes a first source/drain (S/D) region on a first side of the first gate. The LDMOS transistor further includes a second S/D region on a second side of the first gate, wherein the second side is opposite the first side. The LDMOS transistor further includes a first spacer surrounding the first gate. The first spacer includes a first portion on the first side of the first gate, wherein the first portion has a top surface substantially coplanar with a top surface of the first gate, and a second portion on the second side of the first gate, wherein the second portion comprises a first horn structure extending above the top surface of the first gate.

### RELATED APPLICATIONS

This application is a continuation of U.S. application Ser. No. 18/505,257, filed Nov. 9, 2023, which claims the benefit of China Application No. 202311380777.0, filed Oct. 24, 2023, the contents of which are hereby incorporated by reference in their entireties.

### BACKGROUND

As technologies advances in the semiconductor integrated circuit (IC) field, materials, designs and manufacturing processes have enabled a continual reduction in IC device size. The decrease in IC device size, in turn, results in an increase in portability of systems including IC devices. Portable systems often utilize batteries as a basis for providing power to the IC device. In addition, IC devices have increased speed performance designed into the IC device.

Lateral diffusion metal oxide semiconductor (LDMOS) transistors are usable in radio frequency (RF) and microwave applications. LDMOS transistors are used in power amplification circuits, in some instances. Therefore, LDMOS transistors are included in portable IC devices, such as mobile phones, in some instances.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a lateral diffusion metal oxide semiconductor (LDMOS) transistor in accordance with some embodiments.

FIG. 2 is a graph of drain voltage (Vd) versus gate-drain capacitance (Cgd) in accordance with some embodiments.

FIG. 3 is a graph of total gate charge (Qg) versus gate voltage (Vg) in accordance with some embodiments.

FIG. 4 is a flowchart of a method of making an LDMOS transistor in accordance with some embodiments.

FIG. 5 is a cross-sectional view of an LDMOS transistor during an intermediate stage of manufacture in accordance with some embodiments.

FIGS. 6A-6E are cross-sectional views of an LDMOS transistor during various intermediate stages of manufacture in accordance with some embodiments.

FIGS. 7A-7E are cross-sectional views of an LDMOS transistor during various intermediate stages of manufacture in accordance with some embodiments.

FIGS. 8A-8E are cross-sectional views of an LDMOS transistor during various intermediate stages of manufacture in accordance with some embodiments.

FIGS. 9A-9E are cross-sectional views of an LDMOS transistor during various intermediate stages of manufacture in accordance with some embodiments.

FIGS. 10A-10E are cross-sectional views of an LDMOS transistor during various intermediate stages of manufacture in accordance with some embodiments.

FIG. 11 is a schematic view of a buck converter including an LDMOS transistor in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As integrated circuit (IC) devices decrease in size, more IC devices are incorporated into portable systems, such as mobile phones, smart watches, and other internet of things (IoT) systems. Portable systems rely on batteries to power IC devices, in some instances. In order to prolong the use of the portable devices, IC devices having lower power consumption are desired. Also, as the functionality of portable systems increases customers expect higher performance speeds.

The current description includes a lateral diffusion metal oxide semiconductor (LDMOS) transistor that includes a horn structure on a drain side spacer. The horn structure extends upward beyond a top surface of a gate that is surrounded by the spacer. In comparison with other LDMOS transistors that do not include the horn structure, the LDMOS transistor including the horn structure allows a silicide layer to be formed across an entirety of a top surface of the gate. By forming the silicide layer across the entirety of the top surface of the gate, resistance between the gate and a contact structure is reduced in comparison with other approaches. The reduced resistance helps to reduce power consumption by the LDMOS transistor including the horn structure in comparison with other approaches. For example, an LDMOS transistor includes a resist-protection oxide (RPO) that partially overlaps the gate structure. The partial overlap of the gate by the RPO reduces a portion of the gate that is able to be covered by a silicide layer.

The overlapping of the gate by the RPO also reduces an ability to decrease a size of the gate due to an increased risk of device failure due to the RPO compressing a smaller gate. Maintaining a larger gate size to support the RPO results in higher gate-drain capacitance (Cgd) or total gate charge (Qg), in some instances. Total gate charge Qg is an amount of charge injected into a gate in order to cause the transistor to switch between a non-conductive (OFF) state and a conductive (ON) state. The gate-drain capacitance Cgd impacts a delay between applying a voltage to the gate to change an ON/OFF state of the transistor and a change in current at a drain of the transistor. Reducing the total gate charge Qg helps to conserve battery power in portable systems. Minimizing gate-drain capacitance Cgd improves a speed of the transistor in completely switching between ON/OFF states.

In some instances, the inclusion of an RPO in an LDMOS transistor will also reduce a size of a silicide layer over a drain. Similar to the reduced silicide layer over the gate, the reduced silicide layer over the drain increases resistance between the drain and a contact electrically connected to the drain. The increased resistance between the contacts and at least one of the gate or the drain of the LDMOS transistor also increases heat generation by the LDMOS transistor. As a result, heat dissipation concerns are also exacerbated in LDMOS transistors including an RPO in comparison with an LDMOS transistor including the horn structure of the current description.

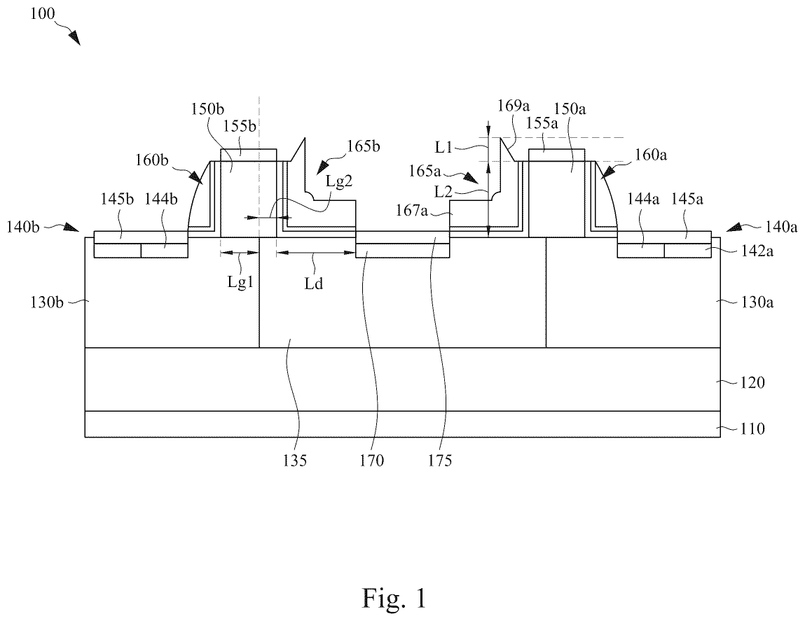

FIG. 1 is a cross-sectional view of an LDMOS transistor 100 in accordance with some embodiments. The LDMOS transistor 100 includes multiple gates 150a and 150b. The LDMOS transistor 100 includes a shared drain 170 between the gates 150a and 150b. While the description of LDMOS transistor 100 below details a multiple gate structure, one of ordinary skill in the art would understand that the description is also applicable to an LDMOS transistor having a single gate structure.

The LDMOS transistor 100 includes a substrate 110. A deep well 120 is within the substrate 110. A plurality of first doped regions 130a and 130b are over the deep well 120 and extend to a top surface of the substrate 110. A second doped region 135 is between the first doped regions 130a and 130b. The second doped region 135 also extends to the top surface of the substrate 110.

A first source region 140a is in an upper portion of the first doped region 130a. A second source region 140b is in an upper portion of the first doped region 130b. Each of the first source region 140a and the second source region 140b are a split source region. For the sake of clarity of the drawings, different portions of the split source region are labeled only in the first source region 140a. The first source region 140a includes a first region 142a and a second region 144a. The second region 144a is between the first region 142a and a neighboring gate 150a. A first source silicide layer 145a is over the first source region 140a. A second source silicide layer 145b is over the second source region 140b.

A first gate 150a is adjacent to the first source region 140a. The first gate 150a is over an interface of the first doped region 130a and the second doped region 135. A first gate silicide layer 155a is over the first gate 150a. A first spacer surrounds the first gate 150a. The first spacer includes a first spacer portion 160a adjacent to the first source 140a. A top surface of the first spacer portion 160a is approximately coplanar with a top surface of the first gate 150a. The first spacer further includes a second spacer portion 165a between the first gate 150a and a drain 170. The second spacer portion 165a includes a bottom region 167a extending from the top surface of the substrate 110 to be approximately co-planar with the top surface of the first gate 150a. A portion of the bottom region 167a farthest from the first gate 150a has a substantially flat top surface. A portion of the bottom region 167a closest to the first gate 150a has a curved top surface. The second spacer portion 165a further includes a top region 169a, also called a horn structure. The top region 169a extends above the top surface of the first gate 150a. The top region 169a extends to a point above the first gate 150a.

The drain region 170 is in the second doped region 135 between the first gate 150a and the second gate 150b. A drain silicide layer 175 is over the drain region 170.

The second gate 150b is similar to the first gate 150a. In some embodiments, the dimensions Lg1, Lg2 and Ld labeled with respect to the second gate 150b are also applicable to the first gate 150a. A second silicide layer 155b is similar to the first silicide layer 155a. A second spacer surrounds the second gate 150b. The second spacer includes a third spacer portion 160b similar to the first spacer portion 160a. The second spacer further includes a fourth spacer portion 165b similar to the second spacer portion 165a. In some embodiments, the dimensions L1 and L2 labeled with respect to the second spacer portion 165a are also applicable to the fourth spacer portion 165b.

The substrate 110 includes a semiconductor material. In some embodiments, the substrate 110 is lightly doped or intrinsically doped. In some embodiments, the substrate 110 is undoped. In some embodiments, the substrate 110 includes silicon. In some embodiments, the substrate 110 includes a silicon on insulator (SOI) substrate. In some embodiments, the substrate 110 has a top surface directly contacting the first gate 150a and the second gate 150b. In some embodiments, the substrate 110 includes a top surface directly contacting the deep well 120 and the deep well 120 and other components are grown on the substrate 110, e.g., using an epitaxial process.

The deep well 120 includes a first dopant type. The deep well 120 provides electrical isolation for the substrate 110. In some embodiments, the first dopant type is p-type, such as boron (B) or boron difluoride (BF₂). In some embodiments, the first dopant type is n-type, such as phosphorous (P) or arsenic (Ar). In some embodiments, the deep well 120 is formed by implanting dopants having the first dopant type into the substrate 110. In some embodiments, an annealing process follows the implantation process to distribute dopants more evenly within the deep well 120. In some embodiments, the deep well 120 is formed by growing a doped epi-layer over the substrate. In some embodiments, the epi-layer is grown and then doped following the epitaxial growing. In some embodiments, the epi-layer is doped in-situ while the epitaxial growing occurs. In some embodiments, a dopant concentration of the deep well 120 ranges from about 10¹⁵ dopants/cm³ to 10¹⁷ dopants/cm³. If the dopant concentration is too large, then a risk of current leakage increases, in some instances. If the dopant concentration is too small, then a risk of failing to electrically isolate the substrate 110 increases, in some instances. In some embodiments, a thickness of the deep well 120 ranges from about 2 microns (μm) to about 3 μm. If the thickness of the deep well 120 is too small, then a risk of failing to sufficiently isolate the substrate 110 increases, in some instances. If the thickness of the deep well 120 is too large, then a size of the LDMOS transistor 100 is increase without appreciable improvement in performance, in some instances.

The deep well 120 extends continuously under both the first gate 150a and the second gate 150b. In some embodiments, the deep well 120 is discontinuous at a location below the second doped region 135 that is offset from both the first gate 150a and the second gate 150b in a plan view.

The first doped regions 130a and 130b are over the deep well 120. Each of the first doped regions 130a and 130b have the first dopant type. In some embodiments, the first doped regions 130a and 130b are formed by implanting dopants having the first dopant type into the substrate 110. In some embodiments, an annealing process follows the implantation process to distribute dopants more evenly within the first doped regions 130a and 130b. In some embodiments, the first doped regions 130a and 130b are formed by growing a doped epi-layer over the substrate 110 or the deep well 120. In some embodiments, the epi-layer is grown and then doped following the epitaxial growing. In some embodiments, the epi-layer is doped in-situ while the epitaxial growing occurs. In some embodiments, a dopant concentration of the first doped regions 130a and 130b ranges from about 10¹⁷ dopants/cm³ to 10¹⁸ dopants/cm³. If the dopant concentration is too large, then a risk of current leakage increases, in some instances. If the dopant concentration is too small, then a risk of failing to sufficiently suppress parasitic bipolar junction transistor (BJT) interactions increases, in some instances. In some embodiments, a thickness of the first doped regions 130a and 130b ranges from about 1 μm to about 2 μm. If the thickness of the first doped regions 130a and 130b is too small, then a risk of failing to sufficiently suppress parasitic BJT interactions increases, in some instances. If the thickness of the first doped regions 130a and 130b is too large, then a size of the LDMOS transistor 100 is increase without appreciable improvement in performance, in some instances.

In some embodiments, the first doped region 130a is equivalent to the first doped region 130b. In some embodiments, the first doped region 130a differs from the first doped region 130b in at least one of dopant concentration, thickness, dopant species, or other suitable parameter.

The second doped region 135 is over the deep well 120. The second doped region 135 has a second dopant type, opposite to the first dopant type. In some embodiments, the second doped region 135 is formed by implanting dopants having the second dopant type into the substrate 110. In some embodiments, an annealing process follows the implantation process to distribute dopants more evenly within the second doped region 135. In some embodiments, the second doped region 135 is formed by growing a doped epi-layer over the substrate 110 or the deep well 120. In some embodiments, the epi-layer is grown and then doped following the epitaxial growing. In some embodiments, the epi-layer is doped in-situ while the epitaxial growing occurs. In some embodiments, a dopant concentration of the second doped region 135 ranges from about 10¹⁷ dopants/cm³ to 10¹⁸ dopants/cm³. If the dopant concentration is too large, then a risk of current leakage increases, in some instances. If the dopant concentration is too small, then a risk of failing to sufficiently suppress parasitic BJT interactions increases, in some instances. In some embodiments, a thickness of the second doped region 135 ranges from about 1 μm to about 2 μm. If the thickness of the second doped region 135 is too small, then a risk of failing to sufficiently suppress parasitic BJT interactions increases, in some instances. If the thickness of the second doped region 135 is too large, then a size of the LDMOS transistor 100 is increased without appreciable improvement in performance, in some instances.

In some embodiments, a thickness of the second doped region 135 is equivalent to the thickness of the first doped regions 130a and 130b. In some embodiments, the thickness of the second doped region 135 is different from a thickness of a least one of the first doped region 130a or the first doped region 130b.

The source regions 140a and 140b are in corresponding first doped regions 130a and 130b. Each of the source regions 140a and 140b are a split source region. In some embodiments, at least one of the source regions 140a and 140b is a not a split source region. The source region 140a includes a first dopant type region 142a and a second dopant type region 144a. The first dopant type region 142a has the first dopant type; and the second dopant type region 144a has the second dopant type. In some embodiments, a thickness of the source regions 140a and 140b ranges from about 0.2 μm to about 0.3 μm. If the thickness of the source regions 140a and 140b is too great, a risk of current leakage increases, in some instances. If the thickness of the source regions 140a and 140b is too small, resistance in the source regions 140a and 140b increases above design specifications, in some instances. In some embodiments, the source regions 140a and 140b are formed by ion implantation. In some embodiments, an annealing process is performed after the ion implantation. In some embodiments, a dopant concentration of the source regions 140a and 140b ranges from about 10²⁰ dopants/cm³ to 10²¹ dopants/cm³. If the dopant concentration is too large, then a risk of current leakage increases, in some instances. If the dopant concentration is too small, then a resistance in the source regions 140a and 140b increases beyond design specifications, in some instances.

The silicide layers 145a and 145b are over corresponding source regions 140a and 140b. The silicide layers 145a and 145b help to reduce resistance between the corresponding source regions 140a and 140b and a contact structure in an IC device including the LDMOS transistor 100. The silicide layers 145a and 145b include silicon and at least one metal. In some embodiments, the at least one metal includes titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals). In some embodiments, the silicide layers 145a and 145b further include germanium. In some embodiments, the silicide layers 145a and 145b are self-aligned silicide (salicide) layers. In some embodiments, the silicide layers 145a and 145b are formed by depositing a layer including the at least one metal mentioned above and then performing an annealing process. In some embodiments, the layer including the at least one metal is deposited using chemical vapor deposition (CVD), physical vapor deposition (PVD), atomic layer deposition (ALD), plating, or another suitable deposition method.

The gates 150a and 150b are over a top surface of the first doped regions 130a and 130b and over a top surface of the second doped region 135. In some embodiments, the gates 150a and 150b include an electrode layer and a gate dielectric layer between the electrode layer and the substrate 110. In some embodiments, the gates 150a and 150b further include at least one of a work function layer, an interfacial layer, a diffusion barrier layer, or another suitable layer. In some embodiments, the gate dielectric layer is between sidewalls of the electrode layer and the corresponding spacer that surrounds the gate 150a or 150b. In some embodiments, sidewalls of the electrode layer directly contact the corresponding spacer that surrounds the gate 150a or 150b.

In some embodiments, the electrode layer includes titanium, aluminum, tantalum carbide, tantalum carbide nitride, tantalum silicon nitride, titanium nitride, tantalum nitride, ruthenium, molybdenum, tungsten, platinum, or combinations thereof. For example, a metal fill layer may include aluminum, tungsten, cobalt, copper, and/or other suitable materials. In some embodiments, the electrode layer is formed by CVD, PVD, plating, and/or other suitable processes. In some embodiments, the gate dielectric layer includes a high-k dielectric material such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba, Sr) TiO₃ (BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k≈3.9). In some embodiments, the gate dielectric layer is formed by chemical oxidation, thermal oxidation, ALD, CVD, and/or other suitable methods. In some embodiments, at least one of the gate 150a or 150b is a dummy gate (non-operational).

The gates 150a and 150b overlap an interface between the second doped region 135 and a corresponding one of the first doped regions 130a or 130b. In some embodiments, a length Lg1 of the gate 150b overlapping the first doped region 130b ranges from about 0.1 μm to about 0.5 μm. If the length Lg1 is too large, then an overall size of the LDMOS transistor 100 is increased without an appreciable increase in performance, in some instances. If the length Lg1 is too small, then a risk of short circuiting between the source 140b and the drain 170 increases, in some instances. In some embodiments, a length Lg2 of the gate 150b overlapping the second doped region 135 ranges from about 0.1 μm to about 0.5 μm. If the length Lg2 is too large, then an overall size of the LDMOS transistor 100 is increased without an appreciable increase in performance, in some instances. If the length Lg2 is too small, then a risk of short circuiting between the source 140b and the drain 170 increases, in some instances. In some embodiments, the gate 150b is entirely over one of the first doped region 130b or the second doped region 135. As noted above, the lengths Lg1 and Lg2 described with respect to the gate 150b are applicable to the gate 150a. In some embodiments, the lengths Lg1 and Lg2 for the gate 150a have a same magnitude of the lengths Lg1 and Lg2 for the gate 150b. In some embodiments, at least one length of Lg1 or Lg2 for the gate 150a has a different magnitude from a length Lg1 or Lg2 for the gate 150b.

The first spacer portion 160a is between the gate 150a and the source 140a. The first spacer portion 160a provides electrical isolation for the gate 150a. In some embodiments, the first spacer portion 160a includes a single dielectric material. In some embodiments, the first spacer portion 160a includes multiple dielectric layers. For example, in some embodiments, the first spacer portion 160a includes a silicon oxide, silicon nitride, silicon oxide (ONO) structure. A top-most surface of the first spacer portion 160a is substantially coplanar with the top surface of the gate 150a. In some embodiments, the first spacer portion 160a is formed by depositing one or more layers of dielectric material followed by an etching process to define a shape of the first spacer portion 160a. In some embodiments, the one or more layers of dielectric material are deposited using CVD, oxidation, or another suitable deposition process. In some embodiments, the etching process includes an anisotropic etching process. In some embodiments, the etching process includes a wet etching process or a dry etching process.

The second spacer portion 165a is between the gate 150a and the drain 170. The second spacer portion 165a provides electrical isolation for the gate 150a. In some embodiments, the second spacer portion 165a includes a single dielectric material. In some embodiments, the second spacer portion 165a includes multiple dielectric layers. For example, in some embodiments, the second spacer portion 165a includes a silicon oxide, silicon nitride, silicon oxide (ONO) structure. A top-most surface of the second spacer portion 165a extends above the top surface of the gate 150a. In some embodiments, the second spacer portion 165a is formed by depositing one or more layers of dielectric material followed by an etching process to define a shape of the second spacer portion 165a. In some embodiments, the one or more layers of dielectric material are deposited using CVD, oxidation, or another suitable deposition process. In some embodiments, the etching process includes an anisotropic etching process. In some embodiments, the etching process includes a wet etching process or a dry etching process.

The second spacer portion 165a includes the bottom region 167a and the top region 169a. A top-most surface of the bottom region 167a is substantially coplanar with the top surface of the gate 150a. In some embodiments, a portion of the bottom region 167a farthest from the gate 150a has a substantially planar top surface. In some embodiments, a portion of the bottom region 167a closest to the gate 150 has a curved top surface. In some embodiments, a thickness L2 of the bottom region 167a (also the thickness of the gate 150b) from a surface of the first doped region 130a or the second doped region 135 ranges from about 0.1 μm to about 0.3 μm. If the thickness L2 is too large, then a size of the LDMOS transistor 100 is increased without an appreciable improvement in performance, in some instances. If the thickness L2 is too small, then a distance between the silicide layer 155a and a channel below the gate 150a is decreased and a risk of short circuit is increased, in some instances.

The top region 169a extends beyond the top surface of the gate 150a. In some embodiments, the top region 169a has a tapered profile. In some embodiments, the tapered profile includes a uniform tapered profile. In some embodiments, the tapered profile includes a curved tapered profile. In some embodiments, the top region 169a narrows to a point at a location farthest from the substrate 110. A material of the top region 169a is a same material as a least a portion of the bottom region 167a. In some embodiments where the bottom region 167a includes multiple layers of dielectric material, the top region 169a includes only a material of a top-most layer of the bottom region 167a. In some embodiments where the bottom region 167a includes multiple layers of dielectric material, the top region 169a includes a material of the top-most layer as well as a material of at least one underlying layer of the bottom region 167a. In some embodiments, a thickness L1 of the top region 169a above the top surface of the gate 150a ranges from greater than zero (0) up to about two-thirds (⅔) of L2. If the thickness L1 is too large, then a size of the LDMOS transistor 100 is increased without an appreciable improvement in performance, in some instances.

The top region 169a provides increased electrical isolation between the gate 150a and other structures within the LDMOS transistor 100 while avoiding including separate insulating material beyond the second spacer portion 165a. Avoiding inclusion of separate insulating materials beyond the second spacer portion 165a helps to reduce manufacturing costs and improve efficiency of manufacturing the LDMOS transistor 100 in comparison with other approaches. Further, in comparison with other approaches that do not include the top region 169a, such as those that include RPO, the LDMOS transistor 100 is able to have the silicide layer 155a extend across an entirety of the top surface of the gate 150a to reduce resistance at the gate 150a. The reduced weight of a structure, such as an RPO, also permits greater reduction in a size of the gate 150a in order to facilitate reduction in size of the LDMOS transistor 100. Further, the ability to reduce a size of the gate 150a due to the presence of the top region 169a helps to improve performance of the LDMOS transistor 100 in comparison with other approaches. For example, the Cgd and Qg of the LDMOS transistor 100 are reduced in comparison with other approaches that do not include the top region 169a.

FIG. 1 is a cross-sectional view of the LDMOS transistor 100. One of ordinary skill in the art would understand that in some embodiments, the first spacer portion 160a and the second spacer portion 165a are part of a continuous first spacer surrounding the gate 150a. For example, in some embodiments, in a plan view, the second spacer portion 165a extends along an entire length of the gate 150a between the gate 150a and the drain 170; and the first spacer portion 160a extends around a remaining portion of the gate 150a. In some embodiments, the second spacer portion 165a extends around approximately half of the gate 150a, i.e., a half closest to the drain 170, in a plan view while the first spacer portion 160a extends around the other half of the gate 150a, i.e., the half closest to the source 140a.

The above description with respect to the first spacer portion 160a is applicable to the third spacer portion 160b adjacent to the gate 150b. In some embodiments, the first spacer portion 160a has a same dimension, shape, and material as the third spacer portion 160b. In some embodiments, the first spacer portion 160a differs from the third spacer portion 160b in at least one of material, dimension or shape.

The above description with respect to the second spacer portion 165a is applicable to the fourth spacer portion 165b adjacent the gate 150b. In some embodiments, the second spacer portion 165a has a same dimension, shape, and material as the fourth spacer portion 165b. In some embodiments, the second spacer portion 165a differs from the fourth spacer portion 165b in at least one of material, dimension or shape.

The drain region 170 is in the second doped region 135. The drain region 170 includes a second dopant type. In some embodiments, a thickness of the drain region 170 ranges from about 0.2 μm to about 0.3 μm. If the thickness of the drain region 170 is too great, a risk of current leakage increases, in some instances. If the thickness of the drain region 170 is too small, resistance in the drain region 170 increases above design specifications, in some instances. In some embodiments, the drain region 170 is formed by ion implantation. In some embodiments, an annealing process is performed after the ion implantation. In some embodiments, a dopant concentration of the drain region 170 ranges from about 10²⁰ dopants/cm³ to 10²¹ dopants/cm³. If the dopant concentration is too large, then a risk of current leakage increases, in some instances. If the dopant concentration is too small, then a resistance in the drain region 170 increases beyond design specifications, in some instances.

In some embodiments, a distance Ld between the drain region 170 and the gate 150b ranges from about 0.2 μm to about 6 μm. If the distance Ld is too small, a risk of short circuiting between the gate 150b and the drain 170 increases, in some instances. If the distance Ld is too great, then an operating speed of the LDMOS transistor 100 decreases, in some instances. A magnitude of the distance Ld is determined partially based on a designed operating voltage of the LDMOS transistor 100. In some embodiments, the designed operating voltage of the LDMOS transistor 100 ranges from about 6 volts (V) to about 60 V. If the operating voltage of the LDMOS transistor 100 is too large, then a risk of damage to the LDMOS transistor 100 and other components in an IC device increases, in some embodiments. If the operating voltage of the LDMOS transistor 100 is too small, then a risk of insufficient power to components in the IC device increases, in some instances. In some embodiments, a breakdown electrical field for the distance Ld ranges from about 0.9×10⁵ V/cm to about 1.1×10⁵ V/cm, where the V is the operating voltage of the LDMOS transistor 100. If the breakdown electrical field of the LDMOS transistor 100 is designed to be too large, then a speed of the LDMOS transistor 100 decreases, in some embodiments. If the breakdown electrical field of the LDMOS transistor 100 is designed to be too small, then a risk of short circuiting between the drain 170 and the gate 150b increases, in some instances.

The above description with respect to a distance between the drain 170 and the gate 150b is applicable to a distance between the drain 170 and the gate 150a. In some embodiments, the distance between the drain 170 and the gate 150b is equal to the distance between the drain 170 and the gate 150a. In some embodiments, the distance between the drain 170 and the gate 150b is different from the distance between the drain 170 and the gate 150a.

The silicide layer 175 is over the drain region 170. The silicide layer 175 helps to reduce resistance between the drain region 170 and a contact structure in an IC device including the LDMOS transistor 100. The silicide layer 175 includes silicon and at least one metal. In some embodiments, the at least one metal includes titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals). In some embodiments, the silicide layer 175 further includes germanium. In some embodiments, the silicide layer 175 is a self-aligned silicide (salicide) layer. In some embodiments, the silicide layer 175 is formed by depositing a layer including the at least one metal mentioned above and then performing an annealing process. In some embodiments, the layer including the at least one metal is deposited using chemical vapor deposition (CVD), physical vapor deposition (PVD), atomic layer deposition (ALD), plating, or another suitable deposition method.

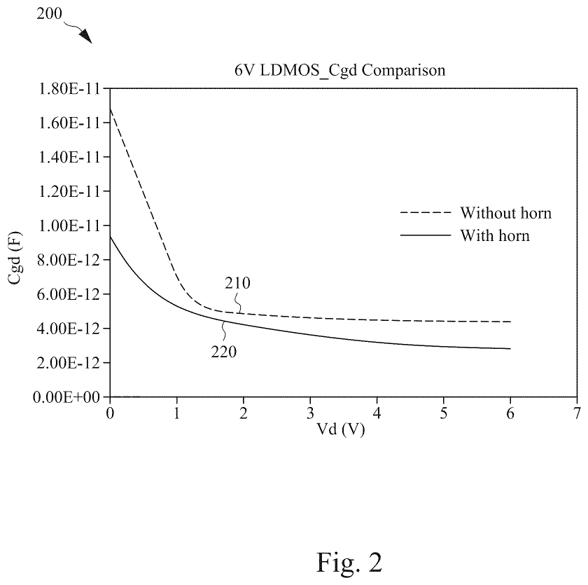

FIG. 2 is a graph 200 of drain voltage (Vd) versus gate-drain capacitance (Cgd) in accordance with some embodiments. The graph 200 is based on LDMOS transistor designed to have an operating voltage of 6V. The graph 200 includes a first plot 210 indicating performance of an LDMOS transistor that does not have a horn, e.g., an LDMOS transistor including an RPO layer partially overlapping a gate. The graph 200 further includes a second plot 220 indicating performance of an LDMOS transistor that includes a horn, e.g., the LDMOS transistor 100 (FIG. 1). The graph 200 indicates that the Cgd for the second plot 220 is significantly less than the Cgd for the first plot 210. As the drain voltage Vd increases to the operating voltage of 6V, the second plot 220 indicates a Cgd about 10% to about 40% less than the first plot 210. This decrease in the Cgd for the second plot 220 indicates that the LDMOS transistor including the horn would have less delay when transitioning between ON/OFF states.

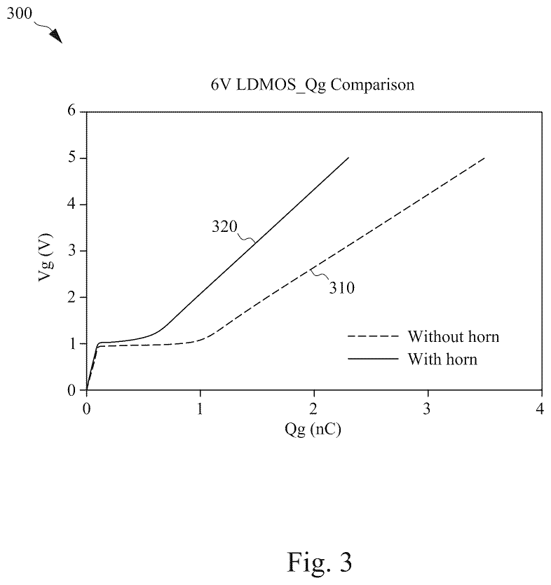

FIG. 3 is a graph 300 of total gate charge (Qg) versus gate voltage (Vg) in accordance with some embodiments. The graph 300 is based on LDMOS transistor designed to have an operating voltage of 6V. The graph 300 includes a first plot 310 indicating performance of an LDMOS transistor that does not have a horn, e.g., an LDMOS transistor including an RPO layer partially overlapping a gate. The graph 300 further includes a second plot 320 indicating performance of an LDMOS transistor that includes a horn, e.g., the LDMOS transistor 100 (FIG. 1). The graph 300 indicates that the Qg for the second plot 320 is significantly less than the Qg for the first plot 310. As the gate voltage Vg increases toward the operating voltage of 6V, the second plot 320 indicates a Qg about 20% to about 30% less than the first plot 310. This decrease in the Qg for the second plot 320 indicates that the LDMOS transistor including the horn would have less delay when transitioning between ON/OFF states.

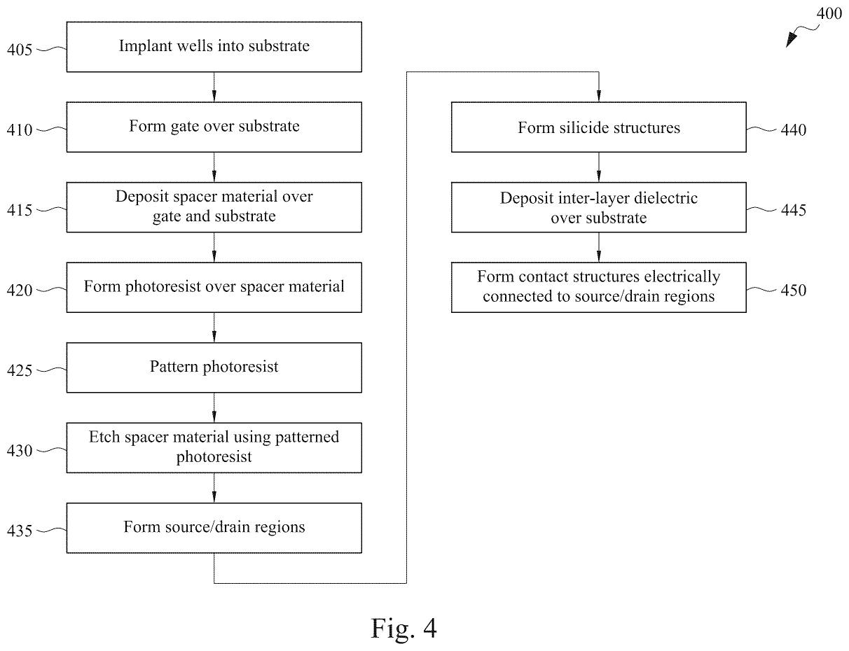

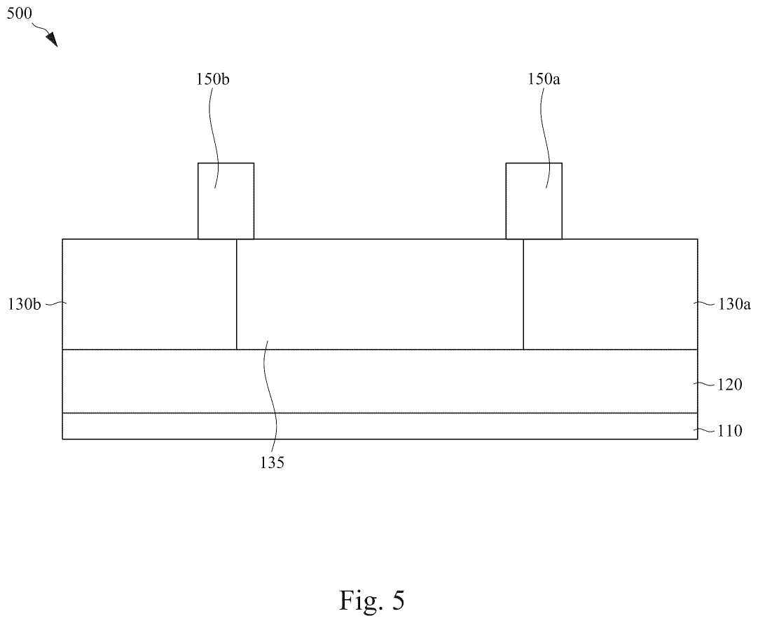

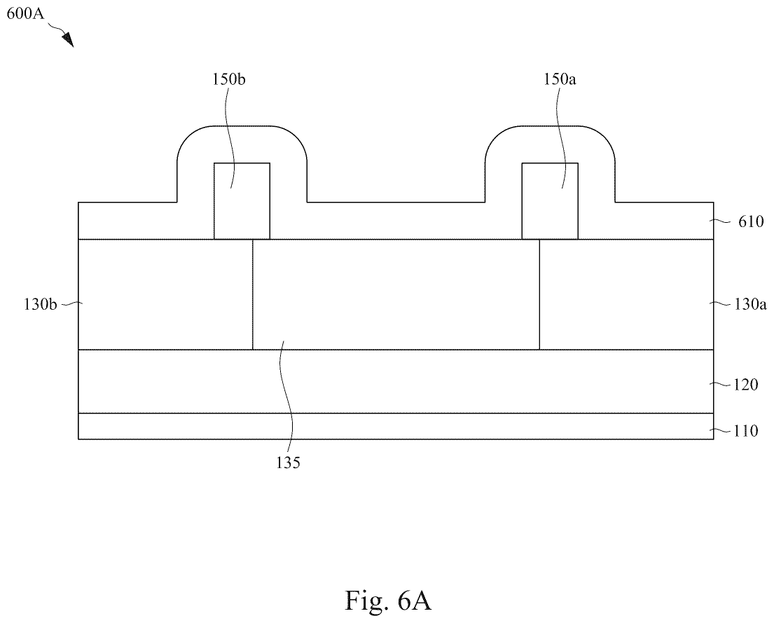

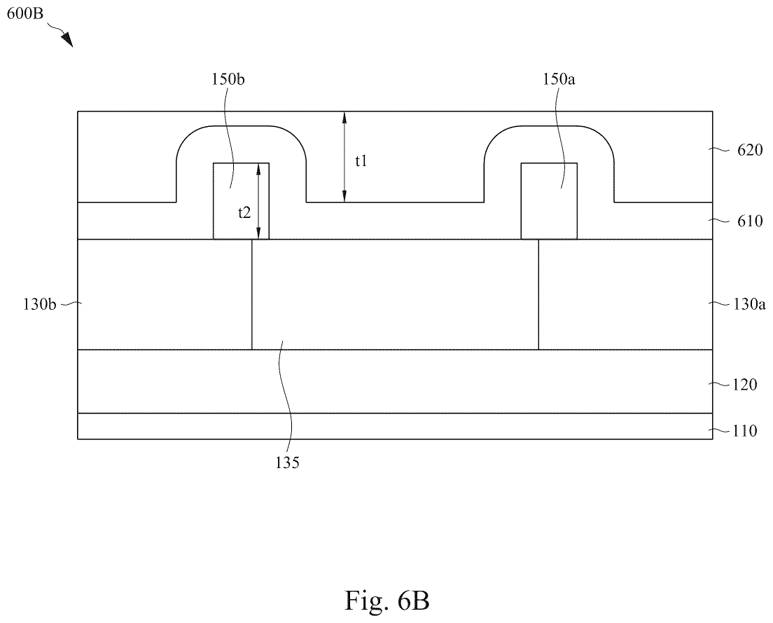

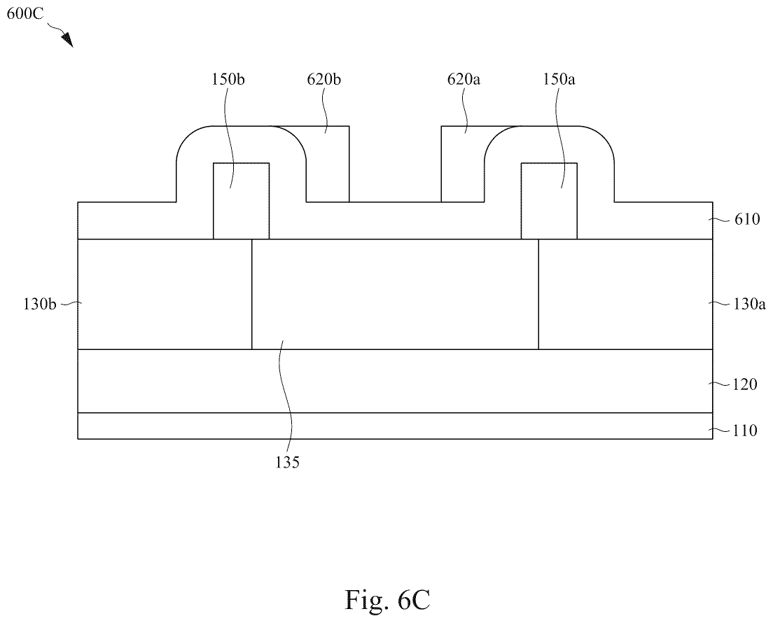

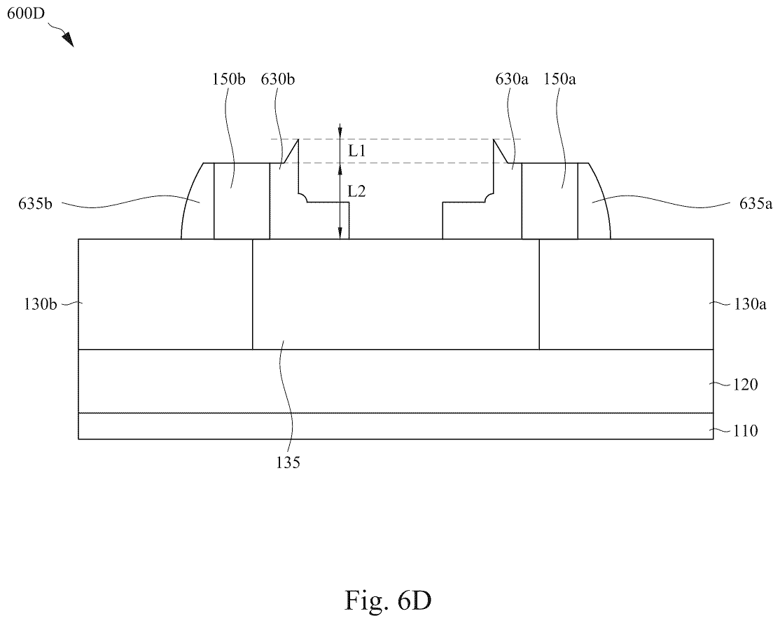

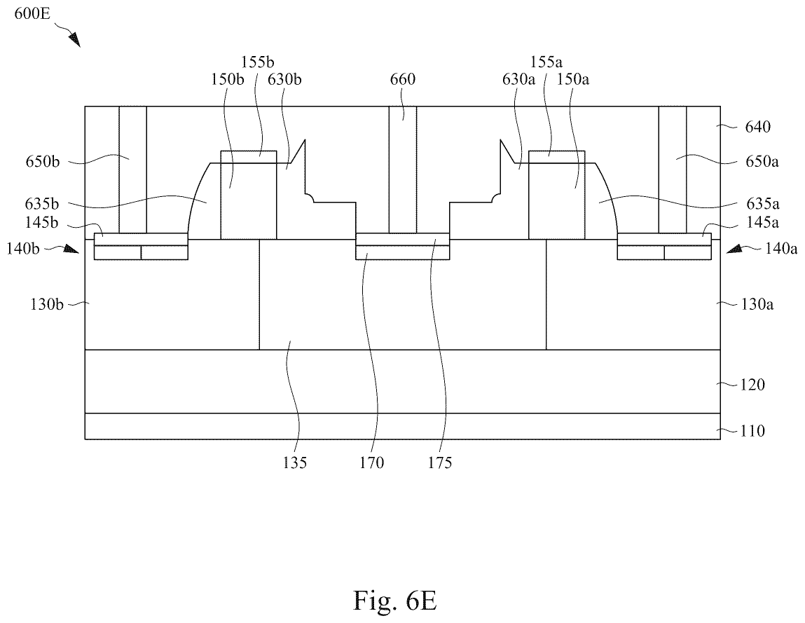

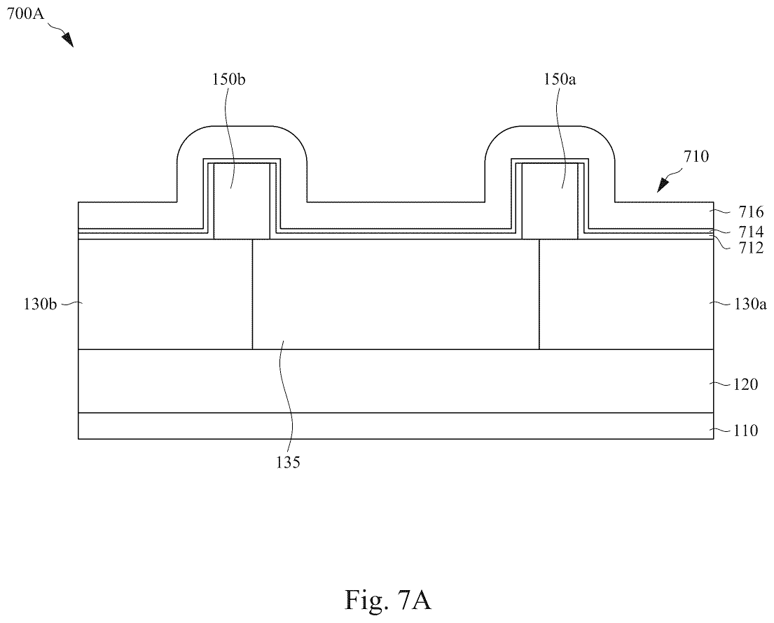

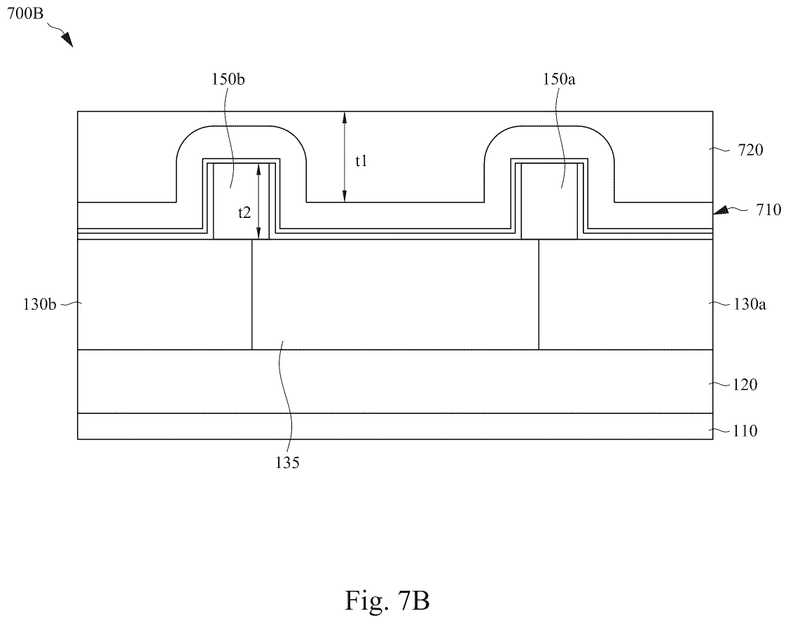

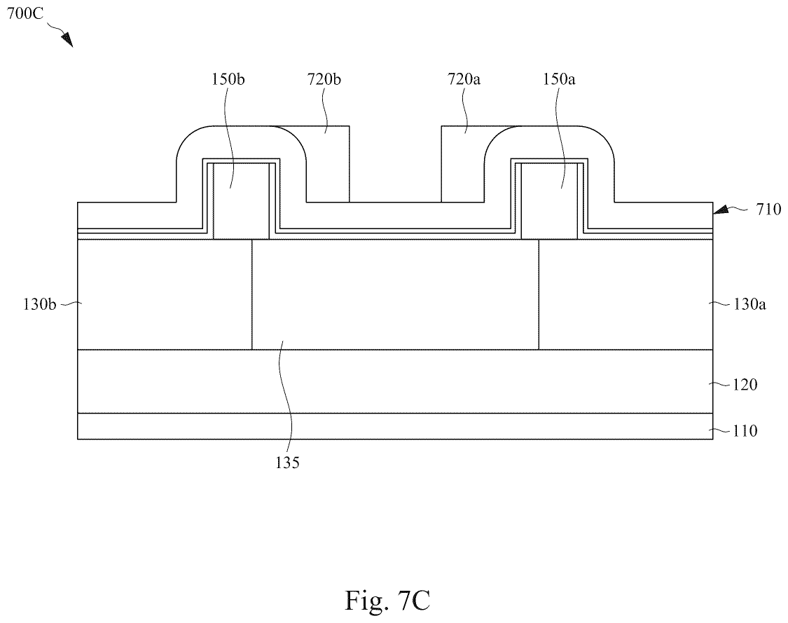

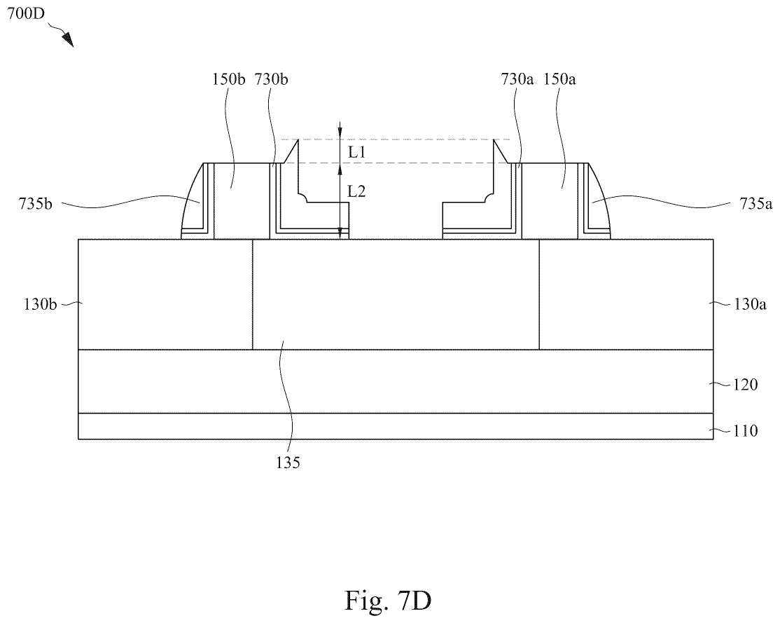

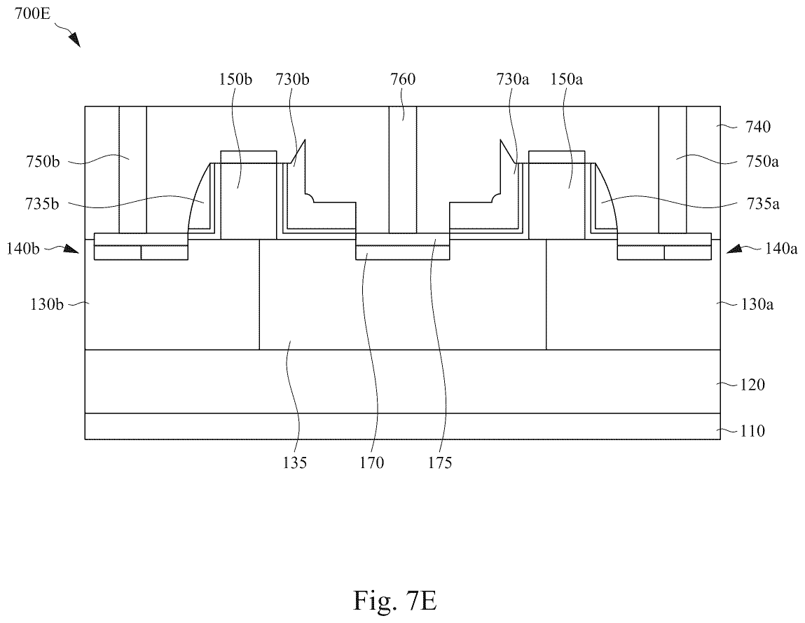

FIG. 4 is a flowchart of a method 400 of making an LDMOS transistor in accordance with some embodiments. In some embodiments, the method 400 is usable to produce the LDMOS transistor 100 (FIG. 1). In some embodiments, the method 400 is usable to produce an LDMOS transistor other than the LDMOS transistor 100 (FIG. 1). For clarity, the method 400 will initially be discussed in combination with cross-sectional views in FIG. 5 and FIGS. 6A-6E. Discussion of some other LDMOS transistors producible by the method 400 will be discussed based on FIGS. 7A-10E following the initial description focusing on some embodiments based on FIGS. 6A-6E.

The method 400 includes operation 405, in which wells are implanted into a substrate. In some embodiments, multiple wells of different depths, dopant concentration, or dopant types are implanted into the substrate. In some embodiments, the implantation process includes ion implantation of dopant species. A power of the implantation process is determined based on a designed depth of the well within the substrate. A dopant concentration is determined based on a designed performance of a corresponding well. A dopant type is determined based on a design of the LDMOS transistor. In some embodiments, the operation 405 is replaced by an operation that includes epitaxially growing one or more layers over the substrate. The one or more epitaxial layers are doped, either in-situ or after the epitaxial process, to define the wells.

In operation 410 a gate is formed over the substrate. In some embodiments, the gate includes a dummy gate. In some embodiments, the dummy gate is subject to a later replacement gate process. In some embodiments, the gate is an active gate. In some embodiments where the gate is a dummy gate, forming the gate includes depositing a layer of polysilicon and patterning the layer of polysilicon to define the gate. In some embodiments where the gate is an active gate, forming the gate includes depositing a gate dielectric layer over the substrate and depositing an electrode layer over the gate dielectric layer. The electrode layer and the gate dielectric layer are then patterned to define the gate. In some embodiments, the patterning includes a combination of photolithography and etching processes.

In some embodiments, depositing the gate dielectric layer includes CVD, oxidation, or other suitable processes. In some embodiments, depositing the electrode layer includes CVD, PVD, plating, ALD, or other suitable processes. In some embodiments, the gate dielectric layer includes silicon oxide. In some embodiments, the gate dielectric layer includes a high-k dielectric material. In some embodiments, the electrode layer includes a metallic layer. In some embodiments, forming the gate includes formation of additional layers, such as at least one work function layer, interfacial layer, diffusion barrier layer, or other suitable layer.

FIG. 5 is a cross-sectional view of a LDMOS transistor 500 at an intermediate stage of production in accordance with some embodiments. In some embodiments, the LDMOS transistor 500 corresponds to formation of the LDMOS transistor 100 (FIG. 1) following operation 410 (FIG. 4) of the method 400. The LDMOS transistor 500 includes the substrate 110; the deep well 120; the first doped regions 130a and 130b; the second doped region 135; and the gates 150a and 150b. In some embodiments, the deep well 120; the first doped regions 130a and 130b; and the second doped region 135 are formed using operation 405 of the method 400 (FIG. 4). In some embodiments, the gates 150a and 150b are formed using the operation 410 of the method 400 (FIG. 4).

Returning to the method 400, in operation 415, a spacer material is deposited over the gate and the substrate. The spacer material includes at least one dielectric material. In some embodiments, the spacer material is blanket deposited over the substrate. In some embodiments, the spacer material is deposited over less than an entirety of the substrate. In some embodiments, the depositing the spacer material includes performing CVD, oxidizing, other suitable processes.

In some embodiments, depositing the spacer material includes depositing a single layer of a dielectric material. In some embodiments, depositing the spacer material includes depositing multiple layers of a single dielectric material. In some embodiments, depositing the spacer material includes depositing layers of different dielectric materials. For example, in some embodiments, the depositing the spacer material includes depositing silicon oxide or silicon nitride. In some embodiments, the depositing the spacer material includes depositing a combination of silicon oxide and silicon nitride, e.g., an ONO structure.

FIG. 6A is a cross-sectional view of a LDMOS transistor 600A at an intermediate stage of production in accordance with some embodiments. In some embodiments, the LDMOS transistor 600A corresponds to a structure after the operation 415 (FIG. 4). In comparison with the LDMOS transistor 500 (FIG. 5), the LDMOS transistor 600A includes spacer material 610 over the substrate 110 and the gates 150a and 150b. The spacer material 610 includes a single layer of silicon oxide. In some embodiments, a thickness of the spacer material 610 ranges from about 1,000 angstroms (A) to about 2,000 A. If the thickness of the spacer material 610 is too great, then a size of the LDMOS transistor 600A is increased without an appreciable increase in performance, in some instances. If the thickness of the spacer material 610 is too small, then the spacer material 610 will not provide sufficient electrical isolation for the gates 150a and 150b, in some instances. In some embodiments, the spacer material 610 is deposited using CVD, oxidation, or other suitable processes. In some embodiments, the spacer material 610 is a conformal layer. In some embodiments, the spacer material 610 is a non-conformal layer.

Returning to FIG. 4, in operation 420 a photoresist is formed over the spacer material. In some embodiments, the photoresist is formed by spin-on coating or other suitable processes. In some embodiments, a baking process is performed after the photoresist is formed on the spacer material. In some embodiments, the photoresist includes a positive photoresist. In some embodiments, the photoresist includes a negative photoresist. In some embodiments, the photoresist includes resin, polymer, or other suitable materials. A maximum thickness of the photoresist is sufficient to cover a top surface of the spacer material. If a maximum thickness of the photoresist is too small, the photoresist remaining after patterning is not sufficient to form a horn structure in the spacer material, in some instances. In some embodiments, a maximum thickness of the photoresist is less than about 1.5 times a thickness of the gate formed in operation 410. If a maximum thickness of the photoresist is too great, photoresist material is wasted without appreciable improvement in performance, in some instances.

FIG. 6B is a cross-sectional view of a LDMOS transistor 600B at an intermediate stage of production in accordance with some embodiments. In some embodiments, the LDMOS transistor 600B corresponds to a structure after the operation 420 (FIG. 4). In comparison with the LDMOS transistor 600A (FIG. 6A), the LDMOS transistor 600B includes photoresist 620 over the spacer material 610. In some embodiments, the photoresist 620 includes resin, polymer, or other suitable materials. The photoresist 620 extends above a top-most surface of the spacer material 610. In some embodiments, a thickness t1 of the photoresist 620 is less than 1.5 times a thickness t2 of the gate 150b (or gate 150a). If the thickness of the photoresist 620 is too great, then photoresist is wasted without an appreciable increase in performance, in some instances. In some embodiments, the thickness t1 of the photoresist 620 is measured at a location between gates 150a and 150b. In some embodiments, the photoresist 620 is deposited using spin-on coating or other suitable processes.

Returning to FIG. 4, in operation 425 the photoresist is patterned. The photoresist is patterned using a combination of photolithography and etching. In some embodiments, the etching is a wet etching. In some embodiments, the etching is a dry etching. The photoresist is patterned to remove portions of the photoresist other than a portion of the photoresist along a sidewall of the spacer material closest to the drain region of the LDMOS. In some embodiments, following patterning of the photoresist, a top surface of the remaining photoresist is substantially coplanar with a top-most surface of the spacer material. In some embodiments where the LDMOS transistor includes multiple gates, the remaining photoresist defines a discontinuous structure where an area of the spacer material over the drain region is free of the photoresist.

FIG. 6C is a cross-sectional view of a LDMOS transistor 600C at an intermediate stage of production in accordance with some embodiments. In some embodiments, the LDMOS transistor 600C corresponds to a structure after the operation 425 (FIG. 4). In comparison with the LDMOS transistor 600B (FIG. 6B), the LDMOS transistor 600C includes remaining photoresist 620a and 620b over sidewalls of the spacer material 610 closest to where a drain region, e.g., drain region 170 (FIG. 1), will be formed in the second doped region 135. Portions of the photoresist 620 (FIG. 6B) other than the remaining photoresist 620a and 620b are removed using a combination of photolithography and etching. The remaining photoresist 620a and 620b defines a discontinuous structure with an opening between the remaining photoresist 620a and the remaining photoresist 620b where the underlying spacer material 610 is exposed. In some embodiments, a top surface of the remaining photoresist 620a and 620b is substantially coplanar with a top-most surface of the spacer material 610.

Returning to FIG. 4, in operation 430 the spacer material is etched using the patterned photoresist as a mask. An etchant used for etching the spacer material is based on a material of the spacer material. In some embodiments, the etching includes a wet etching. In some embodiments, the etching includes a dry etching. In some embodiments, the etchant includes at least one of hydrofluoric acid (HF), sulfuric peroxide mixture (SPM), ammonium peroxide mixture (APM), or other suitable etchants. Since the patterned photoresist protects a sidewall of the spacer material closest to a drain region of the LDMOS, the etching process removes less of the spacer material close to the drain region. As a result, a horn structure is formed by the spacer material on a side of the gate closest to the drain region. In some embodiments, a thickness of the horn structure ranges from greater than o to about two-thirds (⅔) of a thickness of the gate structure. If the thickness of the horn structure is too great, the horn structure interferes with formation of contact structures and negative impacts performance of the LDMOS transistor, in some instances.

FIG. 6D is a cross-sectional view of a LDMOS transistor 600D at an intermediate stage of production in accordance with some embodiments. In some embodiments, the LDMOS transistor 600D corresponds to a structure after the operation 430 (FIG. 4). In comparison with the LDMOS transistor 600C (FIG. 6C), the LDMOS transistor 600D includes a horn structure in the spacer material 610 closest to where a drain region, e.g., drain region 170 (FIG. 1), will be formed in the second doped region 135. The etching process removes portions of the spacer material 610 (FIG. 6C) to define first spacer portion 635a, second spacer portion 630a, third spacer portion 635b, and fourth spacer portion 630b. The second spacer portion 630a and the fourth spacer portion 630b include horn structures. The first spacer portion 635a and the third spacer portion 635b are free of horn structures. A thickness L2 of the gate 150b ranges from about 0.1 μm to about 0.3 μm. If the thickness L2 is too large, then a size of the LDMOS transistor 600D is increased without an appreciable improvement in performance, in some instances. If the thickness L2 is too small, then a distance between a silicide layer, e.g., silicide layer 155a (FIG. 1), and a channel below the gate 150b is decreased and a risk of short circuit is increased, in some instances. In some embodiments, a thickness of the horn structure ranges from greater than o to about two-thirds (⅔) of a thickness of the gate structure. If the thickness of the horn structure is too great, the horn structure interferes with formation of contact structures and negative impacts performance of the LDMOS transistor, in some instances.

Returning to FIG. 4, in operation 435 source/drain (S/D) regions are formed. In some embodiments, the S/D regions are formed by ion implantation. In some embodiments, the S/D regions are formed by removing portions of an underlying substrate to define recesses; and growing S/D regions in the recesses. In some embodiments, the S/D regions are grown in the recesses using epitaxy. In some embodiments, the S/D regions are doped after growing the S/D regions. In some embodiments, the S/D regions are in-situ doped during the growing of the S/D regions. In some embodiments, an annealing process is performed following the doping or implanting of ions.

In operation 440, silicide structures are formed on the S/D regions and on the gates. The silicide structures are formed by depositing a metallic film over the S/D regions and the gates, then annealing the LDMOS transistor to cause a reaction to form silicide. In some embodiments where the electrode layer of the gates includes metal a layer of silicon is deposited over the gates to provide silicon to react with the metallic film in order to form the silicide. The silicide structures over the gates formed by operation 440 extend over an entire length of the gate. This helps to reduce resistance between the gate and a contact structure to improve device performance and reduce power consumption. In some embodiments, the metallic film includes at least one of titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals). In some embodiments, the silicide structures further include germanium. In some embodiments, the silicide structures are self-aligned silicide (salicide) layers. In some embodiments, the metallic film is deposited using CVD, PVD, ALD, plating, or another suitable deposition method.

In operation 445, an inter-layer dielectric (ILD) is deposited over the substrate. The ILD covers the gates, and the spacer material including the horn structure. In some embodiments, a top surface of the ILD is above a top surface of the horn structure. In some embodiments, a top surface of the ILD is substantially coplanar with a top surface of the horn structure. In some embodiments, the ILD includes silicon oxide, silicon nitride, silicon oxynitride, or other suitable dielectric materials. In some embodiments, the ILD is deposited using CVD, ALD, or other suitable deposition processes. In some embodiments, a chemical mechanical polishing (CMP) process is performed following deposition of the ILD.

In operation 450, contact structures are formed to electrically connect to the S/D regions. The contact structures include conductive elements extending through the ILD. The contact structures land on silicide layers of corresponding S/D regions in order to provide electrical connection to the corresponding S/D regions. The contact structures are formed by etching the ILD to define openings in the ILD and then depositing conductive material in the openings. In some embodiments, the etching of the ILD includes a combination of photolithography and etching processes. In some embodiments, the etching is a wet etching. In some embodiments, the etching is a dry etching. In some embodiments, the conducive material is deposited in the openings using CVD, PVD, ALD, plating, or other suitable deposition processes. In some embodiments, additional layers, such as barrier layers, are deposited in the opening between the conductive material and the ILD. In some embodiments, a CMP process is performed following formation of the contact structures.

FIG. 6E is a cross-sectional view of a LDMOS transistor 600E at an intermediate stage of production in accordance with some embodiments. In some embodiments, the LDMOS transistor 600E corresponds to a structure after the operation 450 (FIG. 4). In comparison with the LDMOS transistor 600D (FIG. 6D), the LDMOS transistor 600E includes S/D regions, silicide layers, an ILD and contact structures. For the sake of clarity of the drawings, the split regions of the source regions 140a and 140b are not labeled in FIG. 6E.

The source region 140a is in the first doped region 130a. The silicide layer 145a is over the source region 140a. The source region 140b is in the first doped region 130b. The silicide layer 145b is over the source region 140b. The drain region 170 is in the second doped region 135. The silicide layer 175 is over the drain region 170. Details of embodiments of these features are described above with respect to the LDMOS transistor 100 (FIG. 1).

An ILD 640 is over the gates 150a and 150b as well as the spacer structures that surround the gates 150a and 150b. The ILD 640 has a top surface above a top-most point of the horn structure in the second spacer portion 630a and the fourth spacer portion 630b. In some embodiments, the top surface of the ILD 640 is substantially coplanar with the top-most point of the horn structure in the second spacer portion 630a and the fourth spacer portion 630b. In some embodiments, the ILD 640 includes silicon oxide, silicon nitride, silicon oxynitride, or other suitable dielectric materials.

A first source contact 650a extends through the ILD 640 to electrically connect to the silicide layer 145a to provide electrical connection to the source region 140a. A second source contact 650b extends through the ILD 640 to electrically connect to the silicide layer 145b to provide electrical connection to the source region 140b. A drain contact 660 extends through the ILD 640 to electrically connect to the silicide layer 175 to provide electrical connection to the drain region 170. For the sake of brevity, the first source contact 650a, the second source contact 650b and the drain contact 660 are collectively referred to as the contacts, in some instances.

Each of the contacts has sidewalls that are substantially perpendicular to a top surface of the substrate 110. In some embodiments, at least one of the contacts has a tapered profile. In some embodiments, the contacts independently include at least one of copper, aluminum, tungsten, cobalt, alloys thereof, or other suitable conductive materials. In some embodiments, each of the contacts includes a same conductive material. In some embodiments, at least one contact includes a different conductive material from at least one other contact. In some embodiments, at least one of the contacts further includes a barrier layer to help prevent diffusion of the conductive material into the ILD 640.

Returning to FIG. 4, one of ordinary skill in the art would recognize that modifications to the method 400 are within the scope of this description. In some embodiments, the method 400 includes at least one additional operation. For example, in some embodiments, the method 400 further includes epitaxially growing a semiconductor material over the substrate for implanting wells into the epitaxial layer. In some embodiments, at least one operation of the method 400 is excluded. For example, in some embodiments, the operations 435 and 440 are excluded where the gates are dummy gates and are intended to remain dummy gates in a final product. In some embodiments, an order of operations of the method 400 is modified. For example, in some embodiments, operation 435 is performed prior to operation 415.

FIG. 7A is a cross-sectional view of a LDMOS transistor 700A at an intermediate stage of production in accordance with some embodiments. In some embodiments, the LDMOS transistor 700A corresponds to a structure after the operation 415 (FIG. 4). In comparison with the LDMOS transistor 500 (FIG. 5), the LDMOS transistor 700A includes spacer material 710 over the substrate 110 and the gates 150a and 150b. The spacer material 710 has an ONO structure. The spacer material includes a first silicon oxide layer 712; a silicon nitride layer 714 over the first silicon oxide layer 712; and a second silicon oxide layer 716 over the silicon nitride layer 714. In some embodiments, a total thickness of the spacer material 710 ranges from about 700 A to about 2,800 A. If the thickness of the spacer material 710 is too great, then a size of the LDMOS transistor 700A is increased without an appreciable increase in performance, in some instances. If the thickness of the spacer material 710 is too small, then the spacer material 710 will not provide sufficient electrical isolation for the gates 150a and 150b, in some instances. In some embodiments, a thickness of the first silicon oxide layer 712 ranges from about 100 A to about 300 A. If the thickness of the first silicon oxide layer 712 is too great, then a size of the LDMOS transistor 700A is increased without an appreciable increase in performance, in some instances. If the thickness of the first silicon oxide layer 712 is too small, then the spacer material 710 will not provide sufficient electrical isolation for the gates 150a and 150b, in some instances. In some embodiments, a thickness of the silicon nitride layer 714 ranges from about 200 A to about 500 A. If the thickness of the silicon nitride layer 714 is too great, then a size of the LDMOS transistor 700A is increased without an appreciable increase in performance, in some instances. If the thickness of the silicon nitride layer 714 is too small, then the spacer material 710 will not provide sufficient electrical isolation for the gates 150a and 150b, in some instances. In some embodiments, a thickness of the second silicon oxide layer 716 ranges from about 500 A to about 2,000 A. If the thickness of the second silicon oxide layer 716 is too great, then a size of the LDMOS transistor 700A is increased without an appreciable increase in performance, in some instances. If the thickness of the second silicon oxide layer 716 is too small, then the spacer material 710 will not provide sufficient electrical isolation for the gates 150a and 150b, in some instances. In some embodiments, the spacer material 710 is deposited using CVD, oxidation, or other suitable processes. In some embodiments, the spacer material 710 includes conformal layers. In some embodiments, the spacer material 710 includes non-conformal layers.

FIG. 7B is a cross-sectional view of a LDMOS transistor 700B at an intermediate stage of production in accordance with some embodiments. In some embodiments, the LDMOS transistor 700B corresponds to a structure after the operation 420 (FIG. 4). In comparison with the LDMOS transistor 700A (FIG. 7A), the LDMOS transistor 700B includes photoresist 720 over the spacer material 710. In some embodiments, the photoresist 720 includes resin, polymer, or other suitable materials. The photoresist 720 extends above a top-most surface of the spacer material 710. In some embodiments, a thickness t1 of the photoresist 720 is less than 1.5 times a thickness t2 of the gate 150b (or gate 150a). If the thickness of the photoresist 720 is too great, then photoresist is wasted without an appreciable increase in performance, in some instances. In some embodiments, the thickness t1 of the photoresist 720 is measured at a location between gates 150a and 150b. In some embodiments, the photoresist 720 is deposited using spin-on coating or other suitable processes.

FIG. 7C is a cross-sectional view of a LDMOS transistor 700C at an intermediate stage of production in accordance with some embodiments. In some embodiments, the LDMOS transistor 700C corresponds to a structure after the operation 425 (FIG. 4). In comparison with the LDMOS transistor 700B (FIG. 7B), the LDMOS transistor 700C includes remaining photoresist 720a and 720b over sidewalls of the spacer material 710 closest to where a drain region, e.g., drain region 170 (FIG. 1), will be formed in the second doped region 135. Portions of the photoresist 720 (FIG. 7B) other than the remaining photoresist 720a and 720b are removed using a combination of photolithography and etching. The remaining photoresist 720a and 720b defines a discontinuous structure with an opening between the remaining photoresist 720a and the remaining photoresist 720b where the underlying spacer material 710 is exposed. In some embodiments, a top surface of the remaining photoresist 720a and 720b is substantially coplanar with a top-most surface of the spacer material 710.

FIG. 7D is a cross-sectional view of a LDMOS transistor 700D at an intermediate stage of production in accordance with some embodiments. In some embodiments, the LDMOS transistor 700D corresponds to a structure after the operation 430 (FIG. 4). In comparison with the LDMOS transistor 700C (FIG. 7C), the LDMOS transistor 700D includes a horn structure in the spacer material 710 closest to where a drain region, e.g., drain region 170 (FIG. 1), will be formed in the second doped region 135. The etching process removes portions of the spacer material 710 (FIG. 7C) to define first spacer portion 735a, second spacer portion 730a, third spacer portion 735b, and fourth spacer portion 730b. The second spacer portion 730a and the fourth spacer portion 730b include horn structures. The first spacer portion 735a and the third spacer portion 735b are free of horn structures. A thickness L2 of the gate 150b ranges from about 0.1 μm to about 0.3 μm. If the thickness L2 is too large, then a size of the LDMOS transistor 700D is increased without an appreciable improvement in performance, in some instances. If the thickness L2 is too small, then a distance between a silicide layer, e.g., silicide layer 155a (FIG. 1), and a channel below the gate 150b is decreased and a risk of short circuit is increased, in some instances. In some embodiments, a thickness of the horn structure ranges from greater than o to about two-thirds (⅔) of a thickness of the gate structure. If the thickness of the horn structure is too great, the horn structure interferes with formation of contact structures and negative impacts performance of the LDMOS transistor, in some instances. The LDMOS transistor 700D includes a horn structure that includes only the second silicon oxide layer 716. In some embodiments, the horn structure further includes a portion of the silicon nitride layer 714 and/or a portion of the first silicon oxide layer 712.

FIG. 7E is a cross-sectional view of a LDMOS transistor 700E at an intermediate stage of production in accordance with some embodiments. In some embodiments, the LDMOS transistor 700E corresponds to a structure after the operation 450 (FIG. 4). In comparison with the LDMOS transistor 700D (FIG. 7D), the LDMOS transistor 700E includes S/D regions, silicide layers, an ILD and contact structures. For the sake of clarity of the drawings, the split regions of the source regions 140a and 140b are not labeled in FIG. 7E. For the sake of brevity, details of the S/D regions and silicide layers are not discussed with respect to FIG. 7E.

An ILD 740 is over the gates 150a and 150b as well as the spacer structures that surround the gates 150a and 150b. The ILD 740 has a top surface above a top-most point of the horn structure in the second spacer portion 730a and the fourth spacer portion 730b. In some embodiments, the top surface of the ILD 740 is substantially coplanar with the top-most point of the horn structure in the second spacer portion 730a and the fourth spacer portion 730b. In some embodiments, the ILD 740 includes silicon oxide, silicon nitride, silicon oxynitride, or other suitable dielectric materials.

A first source contact 750a extends through the ILD 740 to electrically connect to the silicide layer 145a to provide electrical connection to the source region 140a. A second source contact 750b extends through the ILD 740 to electrically connect to the silicide layer 145b to provide electrical connection to the source region 140b. A drain contact 760 extends through the ILD 740 to electrically connect to the silicide layer 175 to provide electrical connection to the drain region 170. For the sake of brevity, the first source contact 750a, the second source contact 750b and the drain contact 760 are collectively referred to as the contacts, in some instances.

Each of the contacts has sidewalls that are substantially perpendicular to a top surface of the substrate 110. In some embodiments, at least one of the contacts has a tapered profile. In some embodiments, the contacts independently include at least one of copper, aluminum, tungsten, cobalt, alloys thereof, or other suitable conductive materials. In some embodiments, each of the contacts includes a same conductive material. In some embodiments, at least one contact includes a different conductive material from at least one other contact. In some embodiments, at least one of the contacts further includes a barrier layer to help prevent diffusion of the conductive material into the ILD 740.

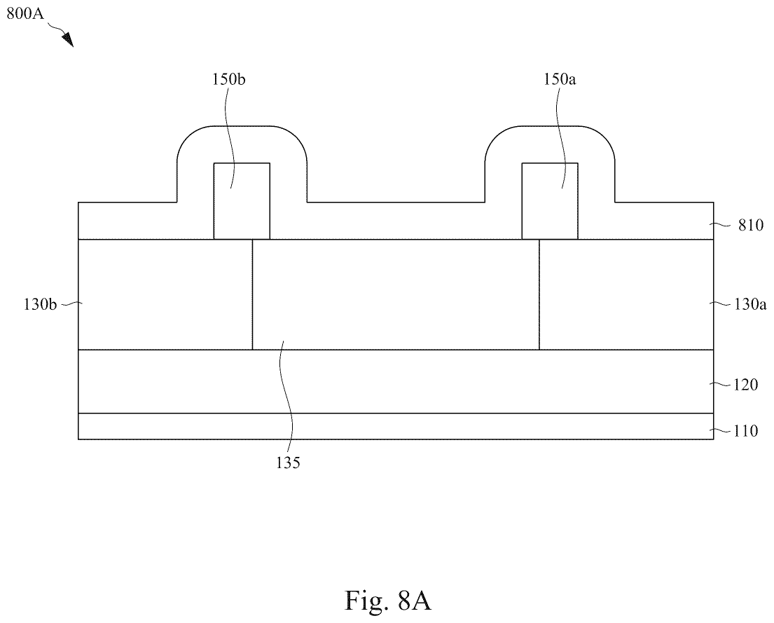

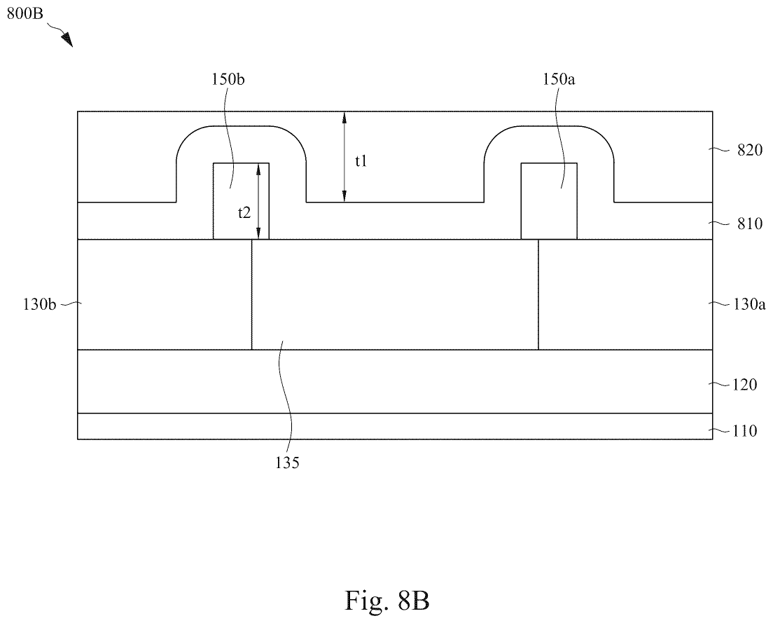

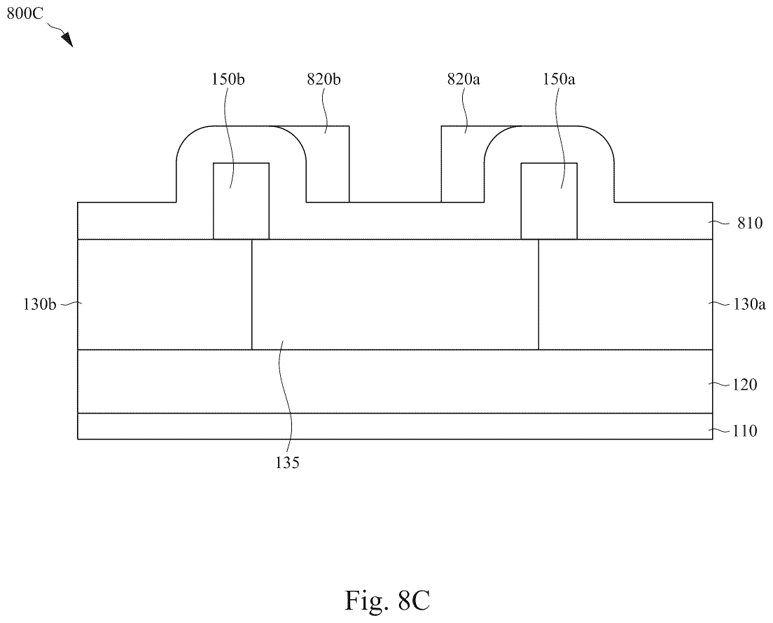

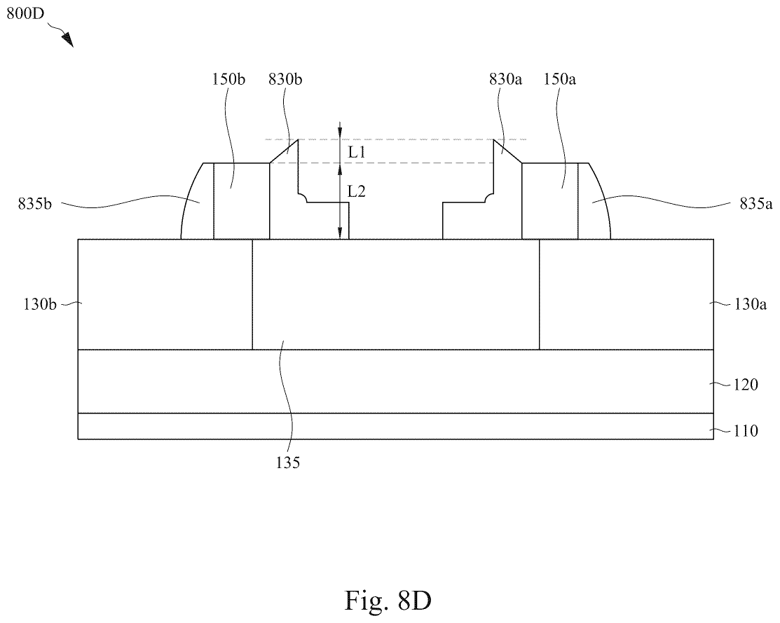

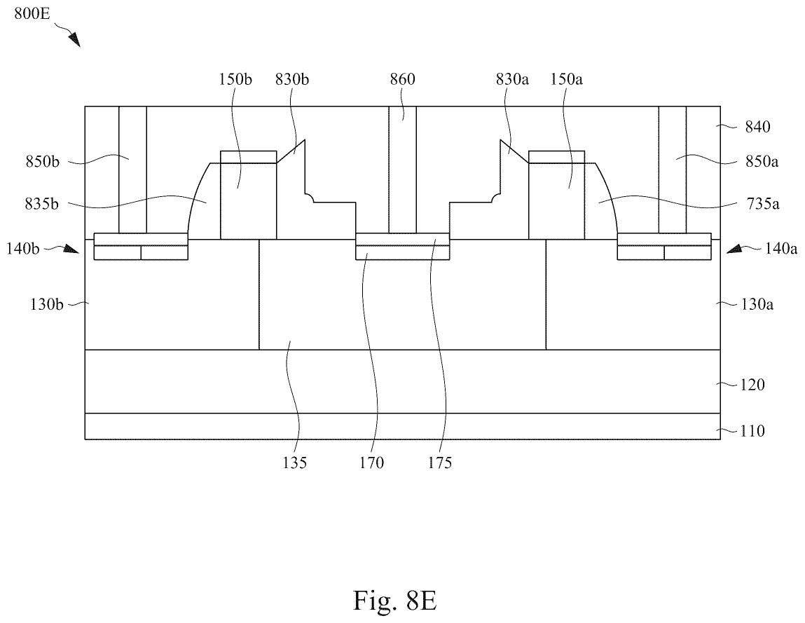

FIG. 8A is a cross-sectional view of a LDMOS transistor 800A at an intermediate stage of production in accordance with some embodiments. In some embodiments, the LDMOS transistor 800A corresponds to a structure after the operation 415 (FIG. 4). In comparison with the LDMOS transistor 500 (FIG. 5), the LDMOS transistor 800A includes spacer material 810 over the substrate 110 and the gates 150a and 150b. The spacer material 810 includes a single layer of silicon nitride. In some embodiments, a thickness of the spacer material 810 ranges from about 1,000 A to about 2,000 A. If the thickness of the spacer material 810 is too great, then a size of the LDMOS transistor 800A is increased without an appreciable increase in performance, in some instances. If the thickness of the spacer material 810 is too small, then the spacer material 810 will not provide sufficient electrical isolation for the gates 150a and 150b, in some instances. In some embodiments, the spacer material 810 is deposited using CVD, oxidation, or other suitable processes. In some embodiments, the spacer material 810 includes a conformal layer. In some embodiments, the spacer material 810 includes a non-conformal layer.

FIG. 8B is a cross-sectional view of a LDMOS transistor 800B at an intermediate stage of production in accordance with some embodiments. In some embodiments, the LDMOS transistor 800B corresponds to a structure after the operation 420 (FIG. 4). In comparison with the LDMOS transistor 800A (FIG. 8A), the LDMOS transistor 800B includes photoresist 820 over the spacer material 810. In some embodiments, the photoresist 820 includes resin, polymer, or other suitable materials. The photoresist 820 extends above a top-most surface of the spacer material 810. In some embodiments, a thickness t1 of the photoresist 820 is less than 1.5 times a thickness t2 of the gate 150b (or gate 150a). If the thickness of the photoresist 820 is too great, then photoresist is wasted without an appreciable increase in performance, in some instances. In some embodiments, the thickness t1 of the photoresist 820 is measured at a location between gates 150a and 150b. In some embodiments, the photoresist 820 is deposited using spin-on coating or other suitable processes.

FIG. 8C is a cross-sectional view of a LDMOS transistor 800C at an intermediate stage of production in accordance with some embodiments. In some embodiments, the LDMOS transistor 800C corresponds to a structure after the operation 425 (FIG. 4). In comparison with the LDMOS transistor 800B (FIG. 8B), the LDMOS transistor 800C includes remaining photoresist 820a and 820b over sidewalls of the spacer material 810 closest to where a drain region, e.g., drain region 170 (FIG. 1), will be formed in the second doped region 135. Portions of the photoresist 820 (FIG. 8B) other than the remaining photoresist 820a and 820b are removed using a combination of photolithography and etching. The remaining photoresist 820a and 820b defines a discontinuous structure with an opening between the remaining photoresist 820a and the remaining photoresist 820b where the underlying spacer material 810 is exposed. In some embodiments, a top surface of the remaining photoresist 820a and 820b is substantially coplanar with a top-most surface of the spacer material 810.

FIG. 8D is a cross-sectional view of a LDMOS transistor 800D at an intermediate stage of production in accordance with some embodiments. In some embodiments, the LDMOS transistor 800D corresponds to a structure after the operation 430 (FIG. 4). In comparison with the LDMOS transistor 800C (FIG. 8C), the LDMOS transistor 800D includes a horn structure in the spacer material 810 closest to where a drain region, e.g., drain region 170 (FIG. 1), will be formed in the second doped region 135. The etching process removes portions of the spacer material 810 (FIG. 8C) to define first spacer portion 835a, second spacer portion 830a, third spacer portion 835b, and fourth spacer portion 830b. The second spacer portion 830a and the fourth spacer portion 830b include horn structures. The first spacer portion 835a and the third spacer portion 835b are free of horn structures. A thickness L2 of the gate 150b ranges from about 0.1 μm to about 0.3 μm. If the thickness L2 is too large, then a size of the LDMOS transistor 800D is increased without an appreciable improvement in performance, in some instances. If the thickness L2 is too small, then a distance between a silicide layer, e.g., silicide layer 155a (FIG. 1), and a channel below the gate 150b is decreased and a risk of short circuit is increased, in some instances. In some embodiments, a thickness of the horn structure ranges from greater than o to about two-thirds (⅔) of a thickness of the gate structure. If the thickness of the horn structure is too great, the horn structure interferes with formation of contact structures and negative impacts performance of the LDMOS transistor, in some instances.

FIG. 8E is a cross-sectional view of a LDMOS transistor 800E at an intermediate stage of production in accordance with some embodiments. In some embodiments, the LDMOS transistor 800E corresponds to a structure after the operation 450 (FIG. 4). In comparison with the LDMOS transistor 800D (FIG. 8D), the LDMOS transistor 800E includes S/D regions, silicide layers, an ILD and contact structures. For the sake of clarity of the drawings, the split regions of the source regions 140a and 140b are not labeled in FIG. 8E. For the sake of brevity, details of the S/D regions and silicide layers are not discussed with respect to FIG. 8E.

An ILD 840 is over the gates 150a and 150b as well as the spacer structures that surround the gates 150a and 150b. The ILD 840 has a top surface above a top-most point of the horn structure in the second spacer portion 830a and the fourth spacer portion 830b. In some embodiments, the top surface of the ILD 840 is substantially coplanar with the top-most point of the horn structure in the second spacer portion 830a and the fourth spacer portion 830b. In some embodiments, the ILD 840 includes silicon oxide, silicon nitride, silicon oxynitride, or other suitable dielectric materials.

A first source contact 850a extends through the ILD 840 to electrically connect to the silicide layer 145a to provide electrical connection to the source region 140a. A second source contact 850b extends through the ILD 840 to electrically connect to the silicide layer 145b to provide electrical connection to the source region 140b. A drain contact 860 extends through the ILD 840 to electrically connect to the silicide layer 175 to provide electrical connection to the drain region 170. For the sake of brevity, the first source contact 850a, the second source contact 850b and the drain contact 860 are collectively referred to as the contacts, in some instances.

Each of the contacts has sidewalls that are substantially perpendicular to a top surface of the substrate 110. In some embodiments, at least one of the contacts has a tapered profile. In some embodiments, the contacts independently include at least one of copper, aluminum, tungsten, cobalt, alloys thereof, or other suitable conductive materials. In some embodiments, each of the contacts includes a same conductive material. In some embodiments, at least one contact includes a different conductive material from at least one other contact. In some embodiments, at least one of the contacts further includes a barrier layer to help prevent diffusion of the conductive material into the ILD 840.

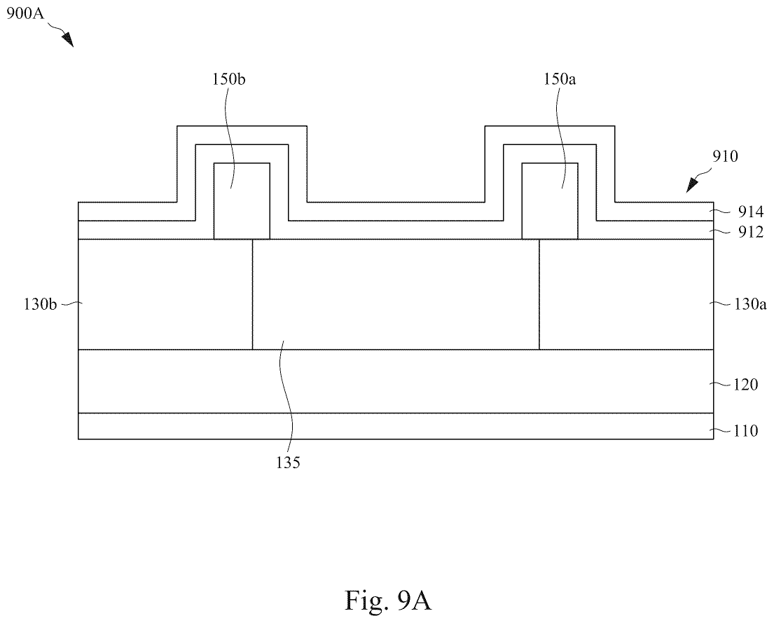

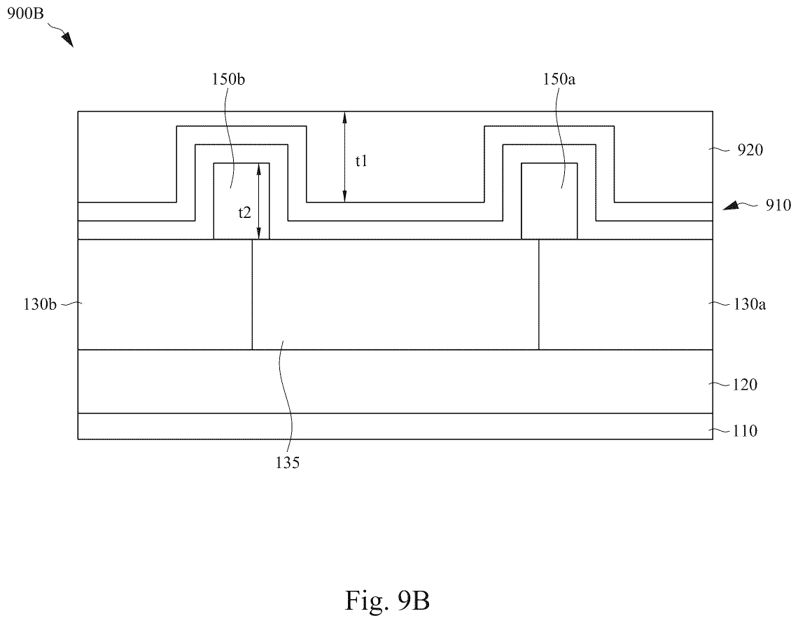

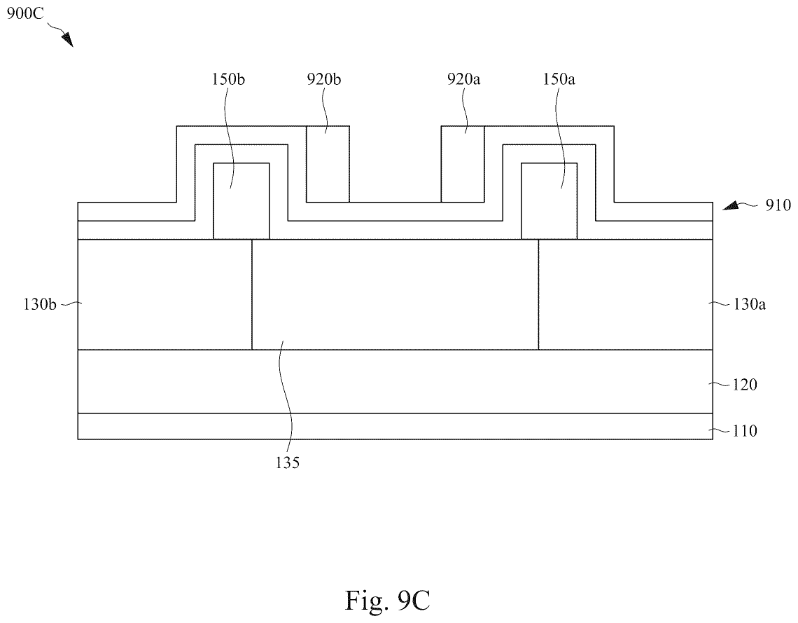

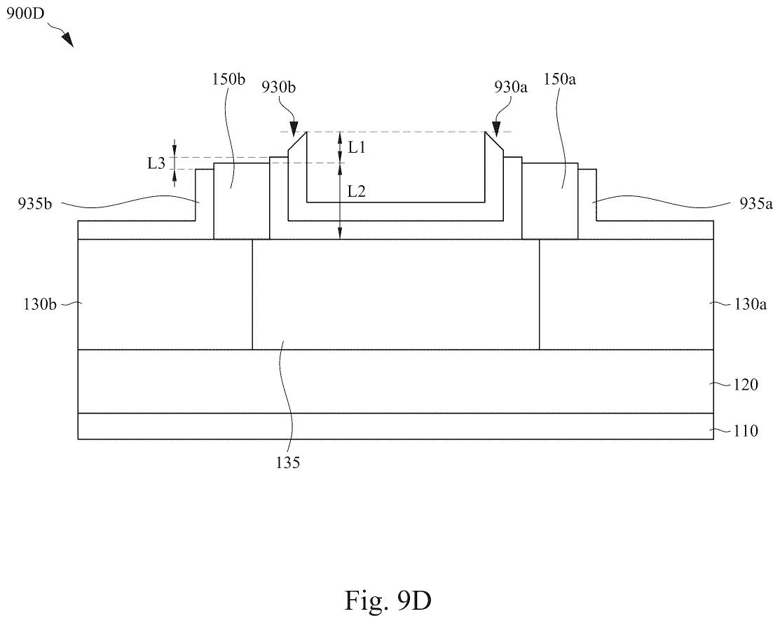

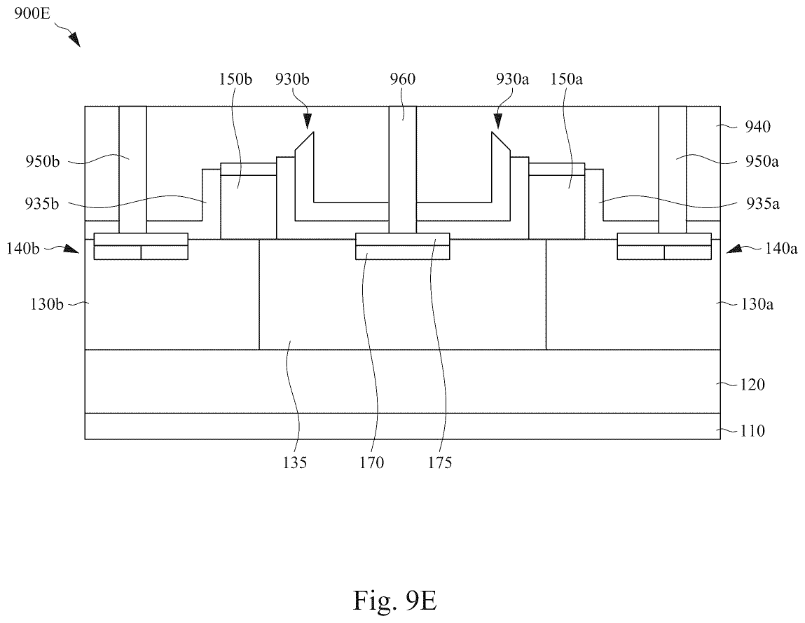

FIG. 9A is a cross-sectional view of a LDMOS transistor 900A at an intermediate stage of production in accordance with some embodiments. In some embodiments, the LDMOS transistor 900A corresponds to a structure after the operation 415 (FIG. 4). In comparison with the LDMOS transistor 500 (FIG. 5), the LDMOS transistor 900A includes spacer material 910 over the substrate 110 and the gates 150a and 150b. The spacer material 910 has a multilayer structure. The spacer material 910 includes a silicon oxide layer 912; and a silicon nitride layer 914 over the silicon oxide layer 912. In some embodiments, a total thickness of the spacer material 910 ranges from about 1,000 A to about 2,000 A. If the thickness of the spacer material 910 is too great, then a size of the LDMOS transistor 900A is increased without an appreciable increase in performance, in some instances. If the thickness of the spacer material 910 is too small, then the spacer material 910 will not provide sufficient electrical isolation for the gates 150a and 150b, in some instances. In some embodiments, a thickness of the silicon oxide layer 912 ranges from about 500 A to about 1,000 A. If the thickness of the silicon oxide layer 912 is too great, then a size of the LDMOS transistor 900A is increased without an appreciable increase in performance, in some instances. If the thickness of the silicon oxide layer 912 is too small, then the spacer material 910 will not provide sufficient electrical isolation for the gates 150a and 150b, in some instances. In some embodiments, a thickness of the silicon nitride layer 914 ranges from about 500 A to about 1,000 A. If the thickness of the silicon nitride layer 914 is too great, then a size of the LDMOS transistor 900A is increased without an appreciable increase in performance, in some instances. If the thickness of the silicon nitride layer 914 is too small, then the spacer material 910 will not provide sufficient electrical isolation for the gates 150a and 150b, in some instances. In some embodiments, the spacer material 910 is deposited using CVD, oxidation, or other suitable processes. In some embodiments, the spacer material 910 includes conformal layers. In some embodiments, the spacer material 910 includes non-conformal layers.

FIG. 9B is a cross-sectional view of a LDMOS transistor 900B at an intermediate stage of production in accordance with some embodiments. In some embodiments, the LDMOS transistor 900B corresponds to a structure after the operation 420 (FIG. 4). In comparison with the LDMOS transistor 900A (FIG. 9A), the LDMOS transistor 900B includes photoresist 920 over the spacer material 910. In some embodiments, the photoresist 920 includes resin, polymer, or other suitable materials. The photoresist 920 extends above a top-most surface of the spacer material 910. In some embodiments, a thickness t1 of the photoresist 920 is less than 1.5 times a thickness t2 of the gate 150b (or gate 150a). If the thickness of the photoresist 920 is too great, then photoresist is wasted without an appreciable increase in performance, in some instances. In some embodiments, the thickness t1 of the photoresist 920 is measured at a location between gates 150a and 150b. In some embodiments, the photoresist 920 is deposited using spin-on coating or other suitable processes.

FIG. 9C is a cross-sectional view of a LDMOS transistor 900C at an intermediate stage of production in accordance with some embodiments. In some embodiments, the LDMOS transistor 900C corresponds to a structure after the operation 425 (FIG. 4). In comparison with the LDMOS transistor 900B (FIG. 9B), the LDMOS transistor 900C includes remaining photoresist 920a and 920b over sidewalls of the spacer material 910 closest to where a drain region, e.g., drain region 170 (FIG. 1), will be formed in the second doped region 135. Portions of the photoresist 920 (FIG. 9B) other than the remaining photoresist 920a and 920b are removed using a combination of photolithography and etching. The remaining photoresist 920a and 920b defines a discontinuous structure with an opening between the remaining photoresist 920a and the remaining photoresist 920b where the underlying spacer material 910 is exposed. In some embodiments, a top surface of the remaining photoresist 920a and 920b is substantially coplanar with a top-most surface of the spacer material 910.

FIG. 9D is a cross-sectional view of a LDMOS transistor 900D at an intermediate stage of production in accordance with some embodiments. In some embodiments, the LDMOS transistor 900D corresponds to a structure after the operation 430 (FIG. 4). In comparison with the LDMOS transistor 900C (FIG. 9C), the LDMOS transistor 900D includes a horn structure in the spacer material 910 closest to where a drain region, e.g., drain region 170 (FIG. 1), will be formed in the second doped region 135. The etching process removes portions of the spacer material 910 (FIG. 9C) to define first spacer portion 935a, second spacer portion 930a, third spacer portion 935b, and fourth spacer portion 930b. The second spacer portion 930a and the fourth spacer portion 930b include horn structures. The first spacer portion 935a and the third spacer portion 935b are free of horn structures. A thickness L2 of the gate 150b ranges from about 0.1 μm to about 0.3 μm. If the thickness L2 is too large, then a size of the LDMOS transistor 900D is increased without an appreciable improvement in performance, in some instances. If the thickness L2 is too small, then a distance between a silicide layer, e.g., silicide layer 155a (FIG. 1), and a channel below the gate 150b is decreased and a risk of short circuit is increased, in some instances. In some embodiments, a thickness L1 of the horn structure ranges from greater than 0 to about two-thirds (⅔) of a thickness of the gate structure. If the thickness L1 of the horn structure is too great, the horn structure interferes with formation of contact structures and negative impacts performance of the LDMOS transistor, in some instances. The LDMOS transistor 900D includes a horn structure that includes both the silicon oxide layer 912 and the silicon nitride layer 914. In some embodiments, the horn structure includes only a portion of the silicon nitride layer 914. In some embodiments, a thickness L3 of the silicon oxide layer 912 in the horn structure ranges from greater than 0 to about one-half (½) of L1. If the thickness L3 is too great, the horn structure interferes with formation of contact structures and negatively impacts performance of the LDMOS transistor, in some instances.

FIG. 9E is a cross-sectional view of a LDMOS transistor 900E at an intermediate stage of production in accordance with some embodiments. In some embodiments, the LDMOS transistor 900E corresponds to a structure after the operation 450 (FIG. 4). In comparison with the LDMOS transistor 900D (FIG. 9D), the LDMOS transistor 900E includes S/D regions, silicide layers, an ILD and contact structures. For the sake of clarity of the drawings, the split regions of the source regions 140a and 140b are not labeled in FIG. 9E. For the sake of brevity, details of the S/D regions and silicide layers are not discussed with respect to FIG. 9E.

An ILD 940 is over the gates 150a and 150b as well as the spacer structures that surround the gates 150a and 150b. The ILD 940 has a top surface above a top-most point of the horn structure in the second spacer portion 930a and the fourth spacer portion 930b. In some embodiments, the top surface of the ILD 940 is substantially coplanar with the top-most point of the horn structure in the second spacer portion 930a and the fourth spacer portion 930b. In some embodiments, the ILD 940 includes silicon oxide, silicon nitride, silicon oxynitride, or other suitable dielectric materials.

A first source contact 950a extends through the ILD 940 to electrically connect to the silicide layer 145a to provide electrical connection to the source region 140a. A second source contact 950b extends through the ILD 940 to electrically connect to the silicide layer 145b to provide electrical connection to the source region 140b. A drain contact 960 extends through the ILD 940 to electrically connect to the silicide layer 175 to provide electrical connection to the drain region 170. For the sake of brevity, the first source contact 950a, the second source contact 950b and the drain contact 960 are collectively referred to as the contacts, in some instances.

Each of the contacts has sidewalls that are substantially perpendicular to a top surface of the substrate 110. In some embodiments, at least one of the contacts has a tapered profile. In some embodiments, the contacts independently include at least one of copper, aluminum, tungsten, cobalt, alloys thereof, or other suitable conductive materials. In some embodiments, each of the contacts includes a same conductive material. In some embodiments, at least one contact includes a different conductive material from at least one other contact. In some embodiments, at least one of the contacts further includes a barrier layer to help prevent diffusion of the conductive material into the ILD 940.

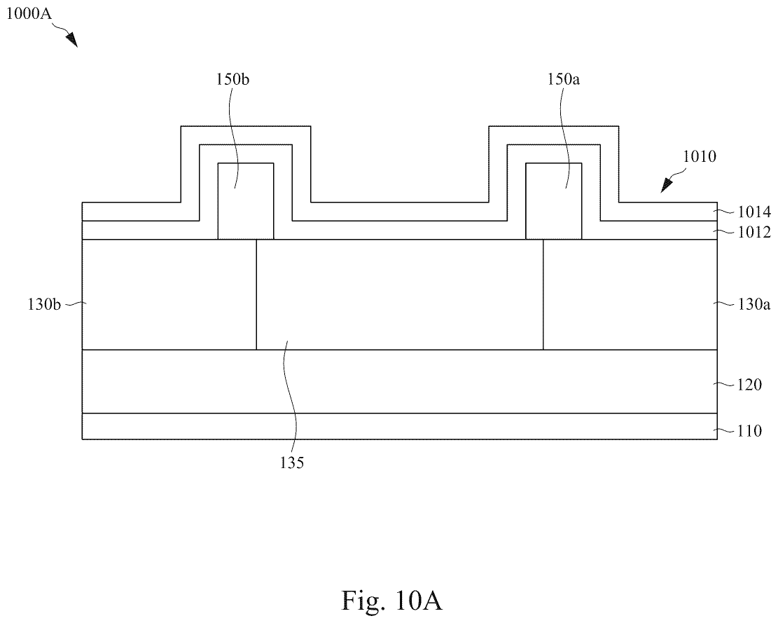

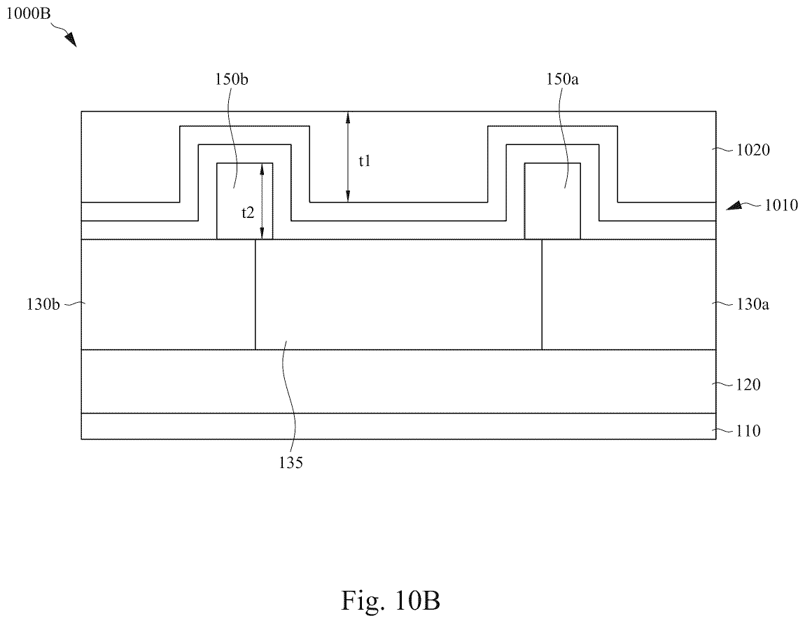

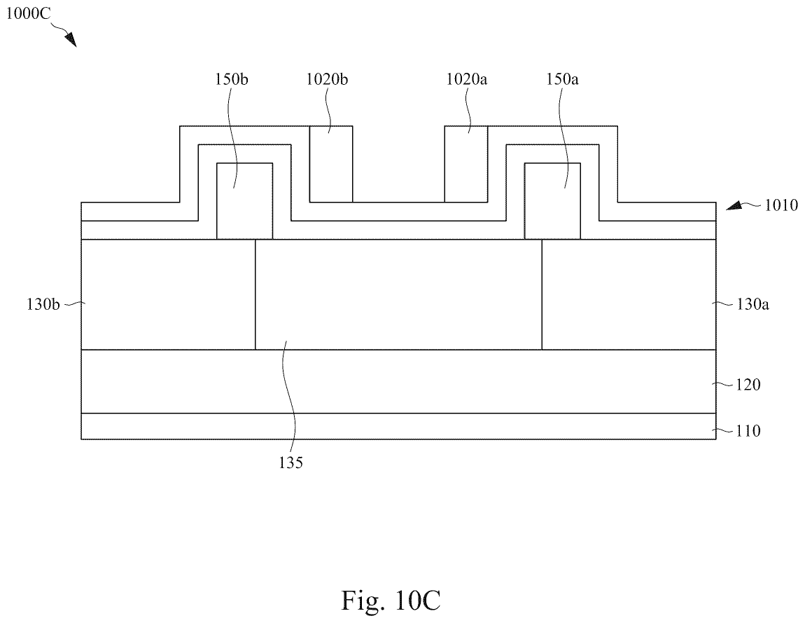

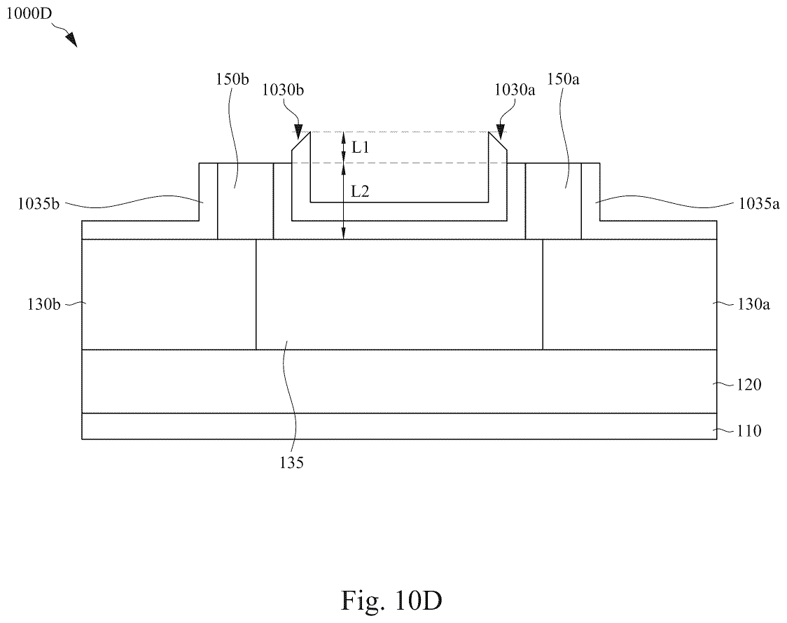

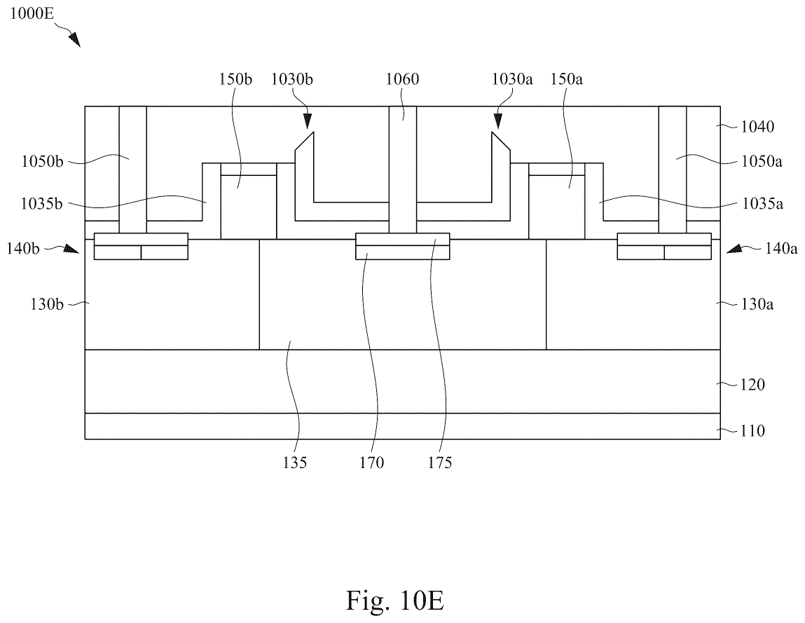

FIG. 10A is a cross-sectional view of a LDMOS transistor 1000A at an intermediate stage of production in accordance with some embodiments. In some embodiments, the LDMOS transistor 1000A corresponds to a structure after the operation 415 (FIG. 4). In comparison with the LDMOS transistor 500 (FIG. 5), the LDMOS transistor 1000A includes spacer material 1010 over the substrate 110 and the gates 150a and 150b. The spacer material 1010 has a multilayer structure. The spacer material 1010 includes a silicon nitride layer 1012; and a silicon oxide layer 1014 over the silicon nitride layer 1012. In some embodiments, a total thickness of the spacer material 1010 ranges from about 1,000 A to about 2,000 A. If the thickness of the spacer material 1010 is too great, then a size of the LDMOS transistor 1000A is increased without an appreciable increase in performance, in some instances. If the thickness of the spacer material 1010 is too small, then the spacer material 1010 will not provide sufficient electrical isolation for the gates 150a and 150b, in some instances. In some embodiments, a thickness of the silicon nitride layer 1012 ranges from about 500 A to about 1,000 A. If the thickness of the silicon nitride layer 1012 is too great, then a size of the LDMOS transistor 1000A is increased without an appreciable increase in performance, in some instances. If the thickness of the silicon nitride layer 1012 is too small, then the spacer material 1010 will not provide sufficient electrical isolation for the gates 150a and 150b, in some instances. In some embodiments, a thickness of the silicon oxide layer 1014 ranges from about 500 A to about 1,000 A. If the thickness of the silicon oxide layer 1014 is too great, then a size of the LDMOS transistor 1000A is increased without an appreciable increase in performance, in some instances. If the thickness of the silicon nitride layer 1014 is too small, then the spacer material 1010 will not provide sufficient electrical isolation for the gates 150a and 150b, in some instances. In some embodiments, the spacer material 1010 is deposited using CVD, oxidation, or other suitable processes. In some embodiments, the spacer material 1010 includes conformal layers. In some embodiments, the spacer material 1010 includes non-conformal layers.

FIG. 10B is a cross-sectional view of a LDMOS transistor 1000B at an intermediate stage of production in accordance with some embodiments. In some embodiments, the LDMOS transistor 1000B corresponds to a structure after the operation 420 (FIG. 4). In comparison with the LDMOS transistor 1000A (FIG. 10A), the LDMOS transistor 1000B includes photoresist 1020 over the spacer material 1010. In some embodiments, the photoresist 1020 includes resin, polymer, or other suitable materials. The photoresist 1020 extends above a top-most surface of the spacer material 1010. In some embodiments, a thickness t1 of the photoresist 1020 is less than 1.5 times a thickness t2 of the gate 150b (or gate 150a). If the thickness of the photoresist 1020 is too great, then photoresist is wasted without an appreciable increase in performance, in some instances. In some embodiments, the thickness t1 of the photoresist 1020 is measured at a location between gates 150a and 150b. In some embodiments, the photoresist 1020 is deposited using spin-on coating or other suitable processes.

FIG. 10C is a cross-sectional view of a LDMOS transistor 1000C at an intermediate stage of production in accordance with some embodiments. In some embodiments, the LDMOS transistor 1000C corresponds to a structure after the operation 425 (FIG. 4). In comparison with the LDMOS transistor 1000B (FIG. 10B), the LDMOS transistor 1000C includes remaining photoresist 1020a and 1020b over sidewalls of the spacer material 1010 closest to where a drain region, e.g., drain region 170 (FIG. 1), will be formed in the second doped region 135. Portions of the photoresist 1020 (FIG. 10B) other than the remaining photoresist 1020a and 1020b are removed using a combination of photolithography and etching. The remaining photoresist 1020a and 1020b defines a discontinuous structure with an opening between the remaining photoresist 1020a and the remaining photoresist 1020b where the underlying spacer material 1010 is exposed. In some embodiments, a top surface of the remaining photoresist 1020a and 1020b is substantially coplanar with a top-most surface of the spacer material 1010.

FIG. 10D is a cross-sectional view of a LDMOS transistor 1000D at an intermediate stage of production in accordance with some embodiments. In some embodiments, the LDMOS transistor 1000D corresponds to a structure after the operation 430 (FIG. 4). In comparison with the LDMOS transistor 1000C (FIG. 10C), the LDMOS transistor 1000D includes a horn structure in the spacer material 1010 closest to where a drain region, e.g., drain region 170 (FIG. 1), will be formed in the second doped region 135. The etching process removes portions of the spacer material 1010 (FIG. 10C) to define first spacer portion 1035a, second spacer portion 1030a, third spacer portion 1035b, and fourth spacer portion 1030b. The second spacer portion 1030a and the fourth spacer portion 1030b include horn structures. The first spacer portion 1035a and the third spacer portion 1035b are free of horn structures. A thickness L2 of the gate 150b ranges from about 0.1 μm to about 0.3 μm. If the thickness L2 is too large, then a size of the LDMOS transistor 1000D is increased without an appreciable improvement in performance, in some instances. If the thickness L2 is too small, then a distance between a silicide layer, e.g., silicide layer 155a (FIG. 1), and a channel below the gate 150b is decreased and a risk of short circuit is increased, in some instances. In some embodiments, a thickness L1 of the horn structure ranges from greater than 0 to about two-thirds (⅔) of a thickness of the gate structure. If the thickness L1 of the horn structure is too great, the horn structure interferes with formation of contact structures and negative impacts performance of the LDMOS transistor, in some instances. The LDMOS transistor 1000D includes a horn structure that includes only silicon oxide layer 1014. In some embodiments, the horn structure of the LDMOS transistor 1000D includes both the silicon nitride layer 1012 and the silicon oxide layer 1014.

FIG. 10E is a cross-sectional view of a LDMOS transistor 1000E at an intermediate stage of production in accordance with some embodiments. In some embodiments, the LDMOS transistor 1000E corresponds to a structure after the operation 450 (FIG. 4). In comparison with the LDMOS transistor 1000D (FIG. 10D), the LDMOS transistor 1000E includes S/D regions, silicide layers, an ILD and contact structures. For the sake of clarity of the drawings, the split regions of the source regions 140a and 140b are not labeled in FIG. 10E. For the sake of brevity, details of the S/D regions and silicide layers are not discussed with respect to FIG. 10E.

An ILD 1040 is over the gates 150a and 150b as well as the spacer structures that surround the gates 150a and 150b. The ILD 1040 has a top surface above a top-most point of the horn structure in the second spacer portion 1030a and the fourth spacer portion 1030b. In some embodiments, the top surface of the ILD 1040 is substantially coplanar with the top-most point of the horn structure in the second spacer portion 1030a and the fourth spacer portion 1030b. In some embodiments, the ILD 1040 includes silicon oxide, silicon nitride, silicon oxynitride, or other suitable dielectric materials.

A first source contact 1050a extends through the ILD 1040 to electrically connect to the silicide layer 145a to provide electrical connection to the source region 140a. A second source contact 1050b extends through the ILD 1040 to electrically connect to the silicide layer 145b to provide electrical connection to the source region 140b. A drain contact 1060 extends through the ILD 1040 to electrically connect to the silicide layer 175 to provide electrical connection to the drain region 170. For the sake of brevity, the first source contact 1050a, the second source contact 1050b and the drain contact 1060 are collectively referred to as the contacts, in some instances.

Each of the contacts has sidewalls that are substantially perpendicular to a top surface of the substrate 110. In some embodiments, at least one of the contacts has a tapered profile. In some embodiments, the contacts independently include at least one of copper, aluminum, tungsten, cobalt, alloys thereof, or other suitable conductive materials. In some embodiments, each of the contacts includes a same conductive material. In some embodiments, at least one contact includes a different conductive material from at least one other contact. In some embodiments, at least one of the contacts further includes a barrier layer to help prevent diffusion of the conductive material into the ILD 1040.

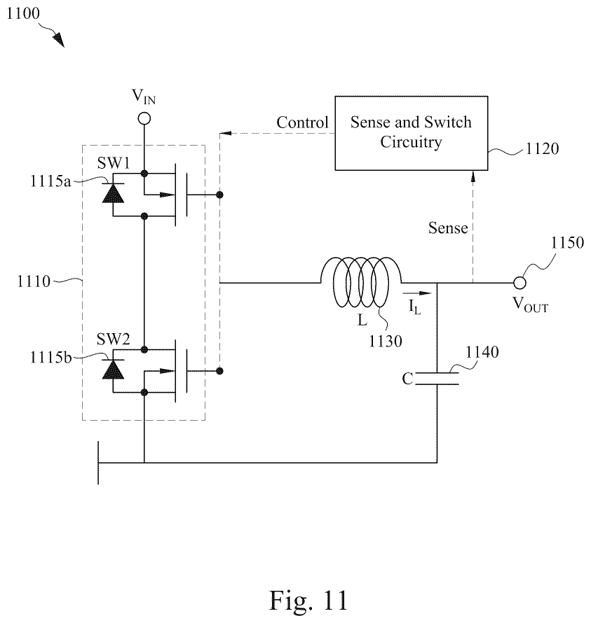

FIG. 11 is a schematic view of a buck converter 1100 including an LDMOS transistor 1110 in accordance with some embodiments. In some embodiments, the LDMOS transistor 1110 is similar to the LDMOS transistor 100 (FIG. 1), the LDMOS transistor 600E (FIG. 6E), the LDMOS transistor 700E (FIG. 7E), the LDMOS transistor 800E (FIG. 8E), the LDMOS transistor 900E (FIG. 9E), or the LDMOS transistor 1000E (FIG. 10E). The buck converter 1100 includes sense and switch circuitry 1120, an inductor 1130, a capacitor 1140, and an output 1150 for providing an output voltage to a load. In some embodiments, the buck converter 1100 includes gate drivers for providing a driving voltage to the gates of the LDMOS transistor 1100.

The sense and switch circuitry 1120 is configured to control a voltage supplied to gates of the LDMOS transistor 1110. A source of a high-side device 1115a is connected to an input voltage Vin. A source of a low-side device 1115b is connected to a reference voltage, e.g., ground. The high-side device 1115a and the low-side device 1115b share a drain, which is connected to the inductor 1130. The capacitor 1140 is connected between an output of the inductor 1130 and the source of the low-side device 1115b. The output voltage (Vout) 1150 is connected to a load.

The LDMOS transistor 1110 includes high-side device 1115a and low-side device 1115b. In some embodiments, the high-side device 1115a corresponds to the gate 150a (FIG. 1); and the low-side device 1115b corresponds to the gate 150b (FIG. 1). In some embodiments where Vᵢₙ is 26.4V, the buck converter 1100 incorporates a high-side device 1115a with a hot carrier injection (HCI) rating of less than 26.4V. The particular HCI rating of interest is a nominal operating area, an HCI 10-year safe operating area, an HCI 0.2-year safe operating area, and/or another suitable HCI rating. To help prevent breakdown behavior, the high-side device 1115a of some embodiments has a breakdown voltage (e.g., BV_{dss}) greater than 26.4V. In order to help achieve these operating characteristics, in some exemplary embodiments, the LDMOS high-side device 1115a has a shorter drift region length, e.g., length Ld, than other approaches.

Similar principles are applicable to the low-side device 1115b. In some embodiments where Vᵢₙ is 26.4V, the buck converter 1100 includes a low-side device 1115b with an HCI rating of less than 26.4V. In some embodiments, an LDMOS low-side device 1115b has a shorter drift region length, e.g., length Ld, than other approaches.

Aspects of this description relate to a lateral diffusion metal-oxide-semiconductor (LDMOS) transistor. The LDMOS transistor includes a first gate. The LDMOS transistor further includes a first source/drain (S/D) region on a first side of the first gate. The LDMOS transistor further includes a second S/D region on a second side of the first gate, wherein the second side is opposite the first side. The LDMOS transistor further includes a first spacer surrounding the first gate. The first spacer includes a first portion on the first side of the first gate, wherein the first portion has a top surface substantially coplanar with a top surface of the first gate, and a second portion on the second side of the first gate, wherein the second portion comprises a first horn structure extending above the top surface of the first gate. In some embodiments, the LDMOS transistor further includes a doped region in a substrate, wherein the second S/D region is in the doped region. In some embodiments, a first portion of the first gate overlaps the doped region, and the first portion has a first dimension parallel to a top surface of the substrate. In some embodiments, a second portion of the first gate is offset from the doped region, and the second portion has a second dimension parallel to the top surface of the substrate. In some embodiments, the first dimension is different from the second dimension. In some embodiments, the first dimension is equal to the second dimension. In some embodiments, the second portion of the first spacer extends for a first distance over the doped region, and the first distance ranges from 0.2 microns (μm) to 6 μm. In some embodiments, the LDMOS transistor further includes a silicide layer over the second S/D region. In some embodiments, the second portion of the first spacer contacts a sidewall of the silicide layer. In some embodiments, the LDMOS transistor further includes a deep well in a substrate, wherein the deep well extends under the first S/D region and the second S/D region.

Aspects of this description relate to a lateral diffusion metal-oxide-semiconductor (LDMOS) transistor. The LDMOS transistor includes a first gate. The LDMOS transistor further includes a second gate. The LDMOS transistor further includes a source/drain (S/D) region between the first gate and the second gate, wherein each of the first gate and the second gate is usable to control a voltage at the S/D region. The LDMOS transistor further includes a first spacer surrounding the first gate. The first spacer includes a first portion on a side of the first gate closest to the S/D region, wherein the first portion comprises a first horn structure extending above a top surface of the first gate. In some embodiments, the LDMOS transistor further includes a contact structure over the S/D region. In some embodiments, the first spacer contacts a first sidewall of the contact structure. In some embodiments, the LDMOS transistor further includes a second spacer surrounding the second gate, wherein the second spacer contacts a second sidewall of the contact structure. In some embodiments, a second portion of the second spacer on a side of the second gate closest to the S/D region comprises a second horn extending above a top surface of the second gate. In some embodiments, the LDMOS transistor further includes a doped region in a substrate, wherein the S/D region is in the doped region. In some embodiments, each of the first gate and the second gate overlaps the doped region.

Aspects of this description relate to a method of making a lateral diffusion metal oxide semiconductor (LDMOS) transistor. The method includes forming a gate over a substrate. The method further includes depositing a spacer material over the gate and the substrate. The method further includes etching the spacer material using a mask. Etching the spacer material includes forming a first portion of the spacer material on a first side of the gate having a top surface substantially coplanar with a top surface of the gate; and forming a horn structure in a second portion of the spacer material on a second side of the gate, wherein the horn structure extends above the top surface of the gate. In some embodiments, a height of the horn structure above the top surface of the gate is less than two-thirds (⅔) of a height of the gate. In some embodiments, forming the gate comprises forming the gate overlapping a doped region of the substrate, and an entirety of the first portion of the spacer overlaps the doped region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lateral diffusion metal-oxide-semiconductor (LDMOS) transistor comprising:
a first gate;
a first source/drain (S/D) region on a first side of the first gate;
a second S/D region on a second side of the first gate, wherein the second side is opposite the first side;
a first spacer surrounding the first gate, wherein the first spacer comprises:
a first portion on the first side of the first gate, wherein the first portion has a top surface substantially coplanar with a top surface of the first gate, and
a second portion on the second side of the first gate, wherein the second portion comprises a first horn structure extending above the top surface of the first gate.

2. The LDMOS transistor of claim 1, further comprising a doped region in a substrate, wherein the second S/D region is in the doped region.

3. The LDMOS transistor of claim 2, wherein a first portion of the first gate overlaps the doped region, and the first portion has a first dimension parallel to a top surface of the substrate.

4. The LDMOS transistor of claim 3, wherein a second portion of the first gate is offset from the doped region, and the second portion has a second dimension parallel to the top surface of the substrate.

5. The LDMOS transistor of claim 4, wherein the first dimension is different from the second dimension.

6. The LDMOS transistor of claim 4, wherein the first dimension is equal to the second dimension.

7. The LDMOS transistor of claim 2, wherein the second portion of the first spacer extends for a first distance over the doped region, and the first distance ranges from 0.2 microns (μm) to 6 μm.

8. The LDMOS transistor of claim 1, further comprising a silicide layer over the second S/D region.

9. The LDMOS transistor of claim 8, wherein the second portion of the first spacer contacts a sidewall of the silicide layer.

10. The LDMOS transistor of claim 1, further comprising a deep well in a substrate, wherein the deep well extends under the first S/D region and the second S/D region.

11. A lateral diffusion metal-oxide-semiconductor (LDMOS) transistor comprising:
a first gate;
a second gate;
a source/drain (S/D) region between the first gate and the second gate, wherein each of the first gate and the second gate is usable to control a voltage at the S/D region;
a first spacer surrounding the first gate, wherein the first spacer comprises:
a first portion on a side of the first gate closest to the S/D region, wherein the first portion comprises a first horn structure extending above a top surface of the first gate.

12. The LDMOS transistor of claim 11, further comprising a contact structure over the S/D region.

13. The LDMOS transistor of claim 12, wherein the first spacer contacts a first sidewall of the contact structure.

14. The LDMOS transistor of claim 12, further comprising a second spacer surrounding the second gate, wherein the second spacer contacts a second sidewall of the contact structure.

15. The LDMOS transistor of claim 14, wherein a second portion of the second spacer on a side of the second gate closest to the S/D region comprises a second horn extending above a top surface of the second gate.

16. The LDMOS transistor of claim 11, further comprising a doped region in a substrate, wherein the S/D region is in the doped region.

17. The LDMOS transistor of claim 16, wherein each of the first gate and the second gate overlaps the doped region.

18. A method of making a lateral diffusion metal oxide semiconductor (LDMOS) transistor, the method comprising:
forming a gate over a substrate;
depositing a spacer material over the gate and the substrate;
etching the spacer material using a mask, wherein etching the spacer material comprises:
forming a first portion of the spacer material on a first side of the gate having a top surface substantially coplanar with a top surface of the gate; and
forming a horn structure in a second portion of the spacer material on a second side of the gate, wherein the horn structure extends above the top surface of the gate.

19. The method of claim 18, wherein a height of the horn structure above the top surface of the gate is less than two-thirds (⅔) of a height of the gate.

20. The method of claim 18, wherein forming the gate comprises forming the gate overlapping a doped region of the substrate, and an entirety of the first portion of the spacer overlaps the doped region.
